(19) United States
(12) Patent Application Publication
(10) Pub. No.: US 2022/0043344 A1
(43) Pub. Date: Feb. 10, 2022

(54) PHOTOSENSITIVE RESIN COMPOSITION, CURED FILM, COLOR FILTER, SOLID-STATE IMAGING ELEMENT AND IMAGE DISPLAY DEVICE

(71) Applicant: FUJIFILM Corporation, Tokyo (JP)

(72) Inventor: Yuki NARA, Shizuoka (JP)

(73) Assignee: FUJIFILM Corporation, Tokyo (JP)

(21) Appl. No.: 17/502,048

(22) Filed: Oct. 15, 2021

Related U.S. Application Data
(63) Continuation of application No. PCT/JP2020/019844, filed on May 20, 2020.

(30) Foreign Application Priority Data
May 24, 2019 (JP) 2019-097698

(51) Int. Cl. G03F 7/038; C09B 47/04; G03F 7/16; G03F 7/38; G03F 7/40; H01L 27/146; G02B 5/23; G02B 5/22

(52) U.S. Cl. CPC G03F 7/038; C09B 47/04; G03F 7/162; G03F 7/38; B82Y 40/00; H01L 27/14621; G02B 5/23; G02B 5/223; G03F 7/40

(57) ABSTRACT

Provided are a photosensitive resin composition including a colorant, a resin, a polymerizable compound, a photopolymerization initiator, an ultraviolet absorber, and a solvent, in which the colorant includes at least one phthalocyanine pigment selected from Color Index Pigment Blue 15:3 or Color Index Pigment Blue 15:4, and includes 50 mass % or more of the phthalocyanine pigment, and the ultraviolet absorber is contained in an amount of 0.1 to 10 mass % in a total solid content of the photosensitive resin composition; a cured film using the photosensitive resin composition; a color filter; a solid-state imaging element; and an image display device.

### CROSS-REFERENCE TO RELATED APPLICATIONS

This application is a Continuation of PCT International Application No. PCT/JP2020/019844 filed on May 20, 2020, which claims priority under 35 U.S.C § 119(a) to Japanese Patent Application No. 2019-097698 filed on May 24, 2019. Each of the above application(s) is hereby expressly incorporated by reference, in its entirety, into the present application.

### BACKGROUND OF THE INVENTION

### 1. Field of the Invention

The present invention relates to a photosensitive resin composition including at least one phthalocyanine pigment selected from Color Index Pigment Blue 15:3 or Color Index Pigment Blue 15:4. The present invention further relates to a cured film formed of the photosensitive resin composition, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

As the color filter, an additive mixing color filter including a red pixel, a green pixel, and a blue pixel, a reduced mixing color filter including a cyan pixel, a magenta pixel, and a yellow pixel, and the like are known. Pixels of each color of the color filter are manufactured using a photosensitive resin composition including a colorant.

Paragraph Nos. 0123 to 0130 of JP2017-142372A discloses a cyan-color photosensitive coloring composition which includes a pigment dispersion including Color Index Pigment Blue 15:3, an acrylic resin solution, a photopolymerizable monomer, a photopolymerization initiator, a leveling agent solution, and a solvent.

JP2018-045189A discloses a photosensitive coloring resin composition for a color filter, including Color Index Pigment Green 7, a blue coloring material, a yellow coloring material, a dispersant, an alkali-soluble resin, a polyfunctional monomer, a photoinitiator, and a solvent. In paragraph No. 0113 of JP2018-045189A, it is disclosed that Pigment Blue 15:3, Pigment Blue 15:4, Pigment Blue 15:6, and the like are used as the blue coloring material.

### SUMMARY OF THE INVENTION

Generally, a color filter has pixels of a plurality of colors. Such a color filter having pixels of a plurality of colors has been manufactured by sequentially forming pixels one by one. For example, in a case where the color filter having pixels of a plurality of colors is formed by a photolithography method using a photosensitive resin composition, the color filter is manufactured by performing an operation, for each pixel of each color, of forming a photosensitive resin composition layer on a support using the photosensitive resin composition, exposing the photosensitive resin composition layer in a patterned manner, and developing and removing a non-exposed portion of the photosensitive resin composition layer to form a pattern (pixel). Therefore, a photosensitive resin composition of another color formed in the next step is also applied to the pixel (hereinafter, also referred to as a first pixel) formed in the previous step. The photosensitive resin composition of another color applied to the pixel (first pixel) formed in the previous step is removed by the development treatment during pattern formation, but in a case where curing properties of the first pixel is insufficient, a colorant or the like included in the photosensitive resin composition of another color applied to the first pixel may move to the first pixel side, and color mixing may occur. Therefore, it is desired that pixels formed by using the photosensitive resin composition have less color mixing with pixels having other hues. In addition, the pixels used for the color filter are also required to have excellent spectral characteristics and light resistance. In addition, in recent years, it has been required to achieve both of these characteristics at a higher level.

By the way, the photosensitive resin composition for forming a cyan-color pixel has not been studied much so far, and it has been difficult to form a cured film such as pixels which can have spectral characteristics suitable for cyan color, light resistance, and suppression of color mixing with pixels of other hues at a high level that has been required in recent years, using a known photosensitive resin composition for forming a cyan pixel in the related art. In addition, according to studies of the present inventor, it has been found that there is room for further improvement in these properties even in the compositions disclosed in JP2017-142372A and JP2018-045189A.

Accordingly, an object of the present invention is to provide a photosensitive resin composition capable of forming a cured film which has spectral characteristics suitable for a development of cyan color, has excellent light resistance, and can suppress occurrence of color mixing with pixels of other hues, a cured film, a color filter, a solid-state imaging element, and an image display device.

As a result of intensive studies by the present inventor, it is found that the cured film having spectral characteristics suitable for cyan color can be formed by increasing, in a colorant included in the photosensitive resin composition, a content of at least one phthalocyanine pigment selected from Color Index (C. I.) Pigment Blue 15:3 or C. I. Pigment Blue 15:4. In addition, in a case where the present inventor further studies the cured film obtained by using this photosensitive resin composition, it is found that there is room for improvement in light resistance. As a result of further studies by the present inventor, it is found that, by using, as the colorant, a colorant including 50 mass % or more of at least one phthalocyanine pigment selected from C. I. Pigment Blue 15:3 or C. I. Pigment Blue 15:4 and containing 0.1 to 10 mass % of an ultraviolet absorber in the total solid content of the photosensitive resin composition, it is possible to form a cured film which has spectral characteristics suitable for cyan color, has excellent light resistance, and can suppress occurrence of color mixing with pixels of other hues, thereby leading to the completion of the present invention. The present invention provides the following.

<1> A photosensitive resin composition comprising:

a colorant;

a resin;

a polymerizable compound;

a photopolymerization initiator;

an ultraviolet absorber; and

a solvent,

in which the colorant includes at least one phthalocyanine pigment selected from Color Index Pigment Blue 15:3 or Color Index Pigment Blue 15:4, and includes 50 mass % or more of the phthalocyanine pigment, and

the ultraviolet absorber is contained in an amount of 0.1 to 10 mass % in a total solid content of the photosensitive resin composition.

<2> The photosensitive resin composition according to <1>,

in which an average secondary particle diameter of the phthalocyanine pigment is 50 to 100 nm.

<3> The photosensitive resin composition according to <1> or <2>,

in which the colorant is included in an amount of 10 mass % or more in the total solid content of the photosensitive resin composition.

<4> The photosensitive resin composition according to any one of <1> to <3>,

in which the resin includes a resin having an amine value of 25 to 60 mgKOH/g.

<5> The photosensitive resin composition according to <4>,

in which the resin having an amine value of 25 to 60 mgKOH/g is a (meth)acrylic resin.

<6> The photosensitive resin composition according to any one of <1> to <5>,

in which the resin includes an alkali-soluble resin.

<7> The photosensitive resin composition according to any one of <1> to <6>,

in which the ultraviolet absorber is included in an amount of 1 to 200 parts by mass with respect to 100 parts by mass of the photopolymerization initiator.

<8> The photosensitive resin composition according to any one of <1> to <7>,

in which the ultraviolet absorber is included in an amount of 0.1 to 100 parts by mass with respect to 100 parts by mass of the polymerizable compound.

<9> The photosensitive resin composition according to any one of <1> to <8>,

in which the photosensitive resin composition is used for forming a pixel of a color filter.

<10> The photosensitive resin composition according to <9>,

in which the photosensitive resin composition is used for forming a cyan pixel.

<11> The photosensitive resin composition according to any one of <1> to <10>, in which the photosensitive resin composition is used for a solid-state imaging element.

<12> A cured film formed from the photosensitive resin composition according to any one of <1> to <11>.

<13> A color filter comprising:

the cured film according to <12>.

<14> A solid-state imaging element comprising:

the cured film according to <12>.

<15> The solid-state imaging element according to <14>,

in which the cured film is a cyan pixel, and

the solid-state imaging element further comprises:
a yellow pixel; and
a magenta pixel.

<16> An image display device comprising:

the cured film according to <12>.

According to the present invention, it is possible to provide a photosensitive resin composition capable of forming a cured film which has spectral characteristics suitable for a development of cyan color, has excellent light resistance, and can suppress occurrence of color mixing with pixels of other hues, a cured film, a color filter, a solid-state imaging element, and an image display device.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright line spectrum of a mercury lamp, a far ultraviolet ray represented by excimer laser, an extreme ultraviolet ray (EUV light), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” denotes not only an individual step but also a step which is not clearly distinguishable from another step as long as an effect expected from the step can be achieved.

<Photosensitive Resin Composition>

A photosensitive resin composition according to an embodiment of the present invention includes a colorant, a resin, a polymerizable compound, a photopolymerization initiator, an ultraviolet absorber, and a solvent, in which the colorant includes at least one phthalocyanine pigment selected from Color Index Pigment Blue 15:3 or Color Index Pigment Blue 15:4, and includes 50 mass % or more of the phthalocyanine pigment, and the ultraviolet absorber is contained in an amount of 0.1 to 10 mass % in a total solid content of the photosensitive resin composition.

According to the photosensitive resin composition according to the embodiment of the present invention, it is possible to form a cured film which has spectral characteristics suitable for a development of cyan color, has excellent light resistance, and can suppress occurrence of color mixing with pixels of other hues. In particular, it is possible to form a cured film having a high average transmittance of light in a wavelength range of 400 to 530 nm and a low average transmittance of light in a wavelength range of 610 to 700 nm. By using, as the colorant, a colorant including 50 mass % or more of at least one phthalocyanine pigment selected from C. I. Pigment Blue 15:3 or C. I. Pigment Blue 15:4, it is possible to form a cured film having spectral characteristics suitable for cyan color. In addition, by using, as the colorant, a colorant including 50 mass % or more of the above-described phthalocyanine pigment and containing 0.1 to 10 mass % of the above-described ultraviolet absorber in the total solid content of the photosensitive resin composition, it is possible to form a cured film which has excellent light resistance and can suppress occurrence of color mixing with pixels of other hues.

In the photosensitive resin composition according to the embodiment of the present invention, in a case where a cured film having a film thickness of 0.4 to 1.0 μm is formed, the average transmittance of light in a wavelength range of 400 to 530 nm in a thickness direction of the film is preferably 70% or more, more preferably 80% or more, and still more preferably 85% or more. In addition, the minimum value of the transmittance of light in the wavelength range of 400 to 530 nm in the thickness direction of the film is preferably 40% or more, more preferably 50% or more, and still more preferably 60% or more. In addition, the average transmittance of light in a wavelength range of 610 to 700 nm in the thickness direction of the film is preferably 30% or less, more preferably 25% or less, and still more preferably 20% or less. In addition, the maximum value of the transmittance of light in the wavelength range of 610 to 700 nm in the thickness direction of the film is preferably 40% or less, more preferably 30% or less, and still more preferably 25% or less.

In the photosensitive resin composition according to the embodiment of the present invention, in a case where a cured film having a film thickness of 0.4 to 1.0 μm is formed, it is preferable that the peak value of the transmittance exists in a wavelength range of 400 to 530 nm in the transmission spectrum of light in a wavelength range of 400 to 700 nm in the thickness direction of the film. In addition, it is preferable that a wavelength having a transmittance of 50% of the peak value (hereinafter, this wavelength is also referred to as λ^{T50}) exists in a wavelength range of 540 to 600 nm. In addition, it is preferable that a wavelength having a transmittance of 20% of the peak value (hereinafter, this wavelength is also referred to as λ^{T20}) exists in a wavelength range of 560 to 620 nm. λ^{T50} preferably exists in a wavelength range of 545 to 595 nm, and more preferably exists in a wavelength range of 550 to 590 nm. λ^{T20} preferably exists in a wavelength range of 565 to 615 nm, and more preferably exists in a wavelength range of 560 to 610 nm. In addition, the difference between λ^{T20} and λ^{T50} (λ^{T20}−λ^{T50}) is preferably 5 to 80 nm, more preferably 7 to 50 nm, and still more preferably 10 to 30 nm.

The value of transmittance of a cured film to be obtained can be appropriately adjusted by changing the content of the at least one phthalocyanine pigment selected from C. I. Pigment Blue 15:3 or C. I. Pigment Blue 15:4, which is included in the colorant, the content of the colorant in the photosensitive resin composition, and the like.

The photosensitive resin composition according to the embodiment of the present invention can be preferably used as a photosensitive resin composition for forming a pixel of a color filter, and can be more preferably used as a photosensitive resin composition for forming a cyan pixel of a color filter.

The photosensitive resin composition according to the embodiment of the present invention can be preferably used as a photosensitive resin composition for an image display device. More specifically, the photosensitive resin composition according to the embodiment of the present invention can be preferably used as a photosensitive resin composition for forming a pixel of a color filter for an image display device, and can be more preferably used as a photosensitive resin composition for forming a cyan pixel of a color filter for an image display device. The type of the image display device is not particularly limited, and examples thereof include a display device having an organic semiconductor element such as an organic electroluminescent display device as a light source.

In addition, the photosensitive resin composition according to the embodiment of the present invention can also be used as a photosensitive resin composition for a solid-state imaging element. More specifically, the photosensitive resin composition according to the embodiment of the present invention can be preferably used as a photosensitive resin composition for forming a pixel of a color filter for a solid-state imaging element, and can be more preferably used as a photosensitive resin composition for forming a cyan pixel of a color filter for a solid-state imaging element.

The thickness of the cured film and pixel formed by the photosensitive resin composition according to the embodiment of the present invention is preferably 0.5 to 3.0 μm. The lower limit is preferably 0.8 μm or more, more preferably 1.0 μm or more, and still more preferably 1.1 μm or more. The upper limit is preferably 2.5 μm or less, more preferably 2.0 μm or less, and still more preferably 1.8 μm or less. In addition, the line width (pattern size) of the pixel formed by the photosensitive resin composition according to the embodiment of the present invention is preferably 2.0 to 10.0 μm. The upper limit is preferably 7.5 μm or less, more preferably 5.0 μm or less, and still more preferably 4.0 μm or less. The lower limit is preferably 2.25 μm or more, more preferably 2.5 μm or more, and still more preferably 2.75 μm or more.

Hereinafter, the photosensitive resin composition according to the embodiment of the present invention will be described in detail.

<<Colorant>>

The photosensitive resin composition according to the embodiment of the present invention contains a colorant. The colorant used in the photosensitive resin composition according to the embodiment of the present invention includes at least one phthalocyanine pigment selected from C. I. Pigment Blue 15:3 or C. I. Pigment Blue 15:4. Hereinafter, C. I. Pigment Blue 15:3 and C. I. Pigment Blue 15:4 are also collectively referred to as a specific phthalocyanine pigment.

From the reason that it is easy to obtain a cured film having spectral characteristics suitable for cyan color by increasing transparency of visible light, the average secondary particle diameter of the specific phthalocyanine pigment is preferably 50 to 100 nm. From the viewpoint of light resistance, the lower limit is preferably 55 nm or more, and more preferably 60 nm or more. From the viewpoint of spectral characteristics, the upper limit is preferably 95 nm or less, and more preferably 90 nm or less.

In the present specification, the average secondary particle diameter of the pigment is measured by directly measuring the size of the secondary particle of the pigment from an electron micrograph using a transmission electron microscope (TEM). Specifically, the minor axis diameter and the major axis diameter of the secondary particle of each pigment are measured, and the average thereof is defined as the particle diameter of the pigment. Next, for each of the 100 pigments, the volume of each pigment is obtained by approximating it to a cube having the obtained particle diameter, and the volume average particle diameter is defined as the average secondary particle diameter.

The colorant used in the photosensitive resin composition according to the embodiment of the present invention contains 50 mass % or more of the specific phthalocyanine pigment, preferably 55 mass % or more, more preferably 60 mass % or more, and still more preferably 65 mass % or more. The upper limit may be 100 mass %, 95 mass % or less, or 90 mass % or less.

The colorant used in the photosensitive resin composition according to the embodiment of the present invention may be a colorant which includes, as the specific phthalocyanine pigment, both C. I. Pigment Blue 15:3 and C. I. Pigment Blue 15:4, or may be a colorant which includes only one of these. In a case where the photosensitive resin composition according to the embodiment of the present invention includes C. I. Pigment Blue 15:3, it is easy to improve application properties of the photosensitive resin composition. In a case where the photosensitive resin composition according to the embodiment of the present invention includes C. I. Pigment Blue 15:4, it is easy to improve storage stability of the photosensitive resin composition and heat resistance of the cured film to be obtained. In addition, in a case where the colorant used in the photosensitive resin composition according to the embodiment of the present invention includes C. I. Pigment Blue 15:3 and C. I. Pigment Blue 15:4, the mass ratio of C. I. Pigment Blue 15:3 and C. I. Pigment Blue 15:4 is preferably 10 to 1000 parts by mass of C. I. Pigment Blue 15:4, more preferably 25 to 400 parts by mass of C. I. Pigment Blue 15:4, and still more preferably 50 to 200 parts by mass of C. I. Pigment Blue 15:4 with respect to 100 parts by mass of C. I. Pigment Blue 15:3.

The colorant used in the photosensitive resin composition according to the embodiment of the present invention may contain a colorant other than the above-described specific phthalocyanine pigment (hereinafter, also referred to as other colorants). In a case of containing other colorants, it can be expected to have better light resistance and improved color separation from pixels of other colors. In a case where, the colorant used in the photosensitive resin composition according to the embodiment of the present invention further contains other colorants, the content of the other colorants in the colorant is preferably less than 50 mass %, more preferably less than 45 mass %, still more preferably less than 40 mass %, even more preferably less than 35 mass %, and particularly preferably less than 30 mass %. The lower limit is preferably 10 mass % or more and more preferably 20 mass % or more.

In addition, it is also preferable that the colorant used in the photosensitive resin composition according to the embodiment of the present invention does not substantially contain other colorants. According to this aspect, it is possible to increase the amount of transmitted light and obtain high-sensitive pixels. The case where the colorant does not substantially contain other colorants means that the content of other colorants in the colorant is less than 0.5 mass %, preferably less than 0.1 mass % and more preferably 0 mass %.

Examples of the other colorants include chromatic colorants such as a red colorant, a green colorant, a blue colorant, a yellow colorant, a violet colorant, and an orange colorant, and a green colorant, a blue colorant, or a yellow colorant is preferable, and from the reason that it is easy to obtain more excellent light resistance, a yellow colorant is more preferable. The other colorants may be either a pigment or a dye. The pigment and the dye may be used in combination. In addition, the pigment may be either an inorganic pigment or an organic pigment. In addition, as the pigment, a material in which a part of an inorganic pigment or an organic-inorganic pigment is replaced with an organic chromophore can also be used. By substituting a part of an inorganic pigment or an organic-inorganic pigment with an organic chromophore, hue design can be easily performed. Examples of the pigment include the following pigments:

C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 231, 232 (methine-based), 233 (quinoline-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), 295 (azo-based), 296 (azo-based), and the like (all of which are red pigments);

C. I. Pigment Green 7, 10, 36, 37, 58, 59, 62, 63, and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:6, 16, 22, 29, 60, 64, 66, 79, 80, 87 (monoazo-based), 88 (methine-based), and the like (all of which are blue pigments).

In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include compounds described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, and the like can also be used.

In addition, as the blue pigment, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

In addition, as the yellow pigment, compounds described in JP2017-201003A, compounds described in JP2017-197719A, compounds described in paragraph Nos. 0011 to “0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432077B, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), and a compound represented by Formula (QP2) can also be used.

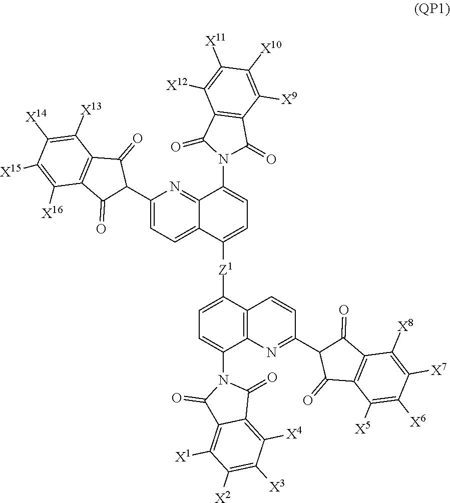

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

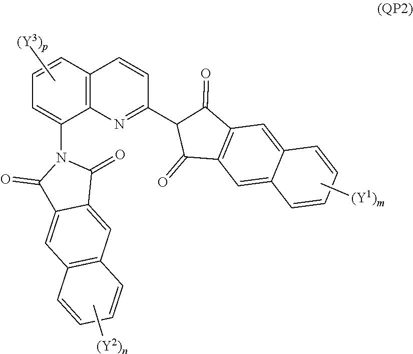

In Formula (QP2), Y¹ to Y³ each independently represent a halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

As the red pigment, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

As the dye, a known dye can be used without any particular limitation. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethene-based dye. In addition, thiazole compounds described in JP2012-158649A, azo compounds described in JP2011-184493A, or azo compounds described in JP2011-145540A can also be preferably used. In addition, as yellow dyes, quinophthalone compounds described in paragraph Nos. 0011 to 0034 of JP2013-054339A, quinophthalone compounds described in paragraph Nos. 0013 to 0058 of JP2014-026228A, or the like can also be used.

The other colorants may be a coloring agent multimer. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. The weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less. As the coloring agent multimer, the compounds described in JP2011-213925A, JP2013-041097A, JP2015-028144A, JP2015-030742A, WO2016/031442A, or the like can also be used.

The content of the colorant in the total solid content of the photosensitive resin composition is preferably 10 mass % or more, more preferably 15 mass % or more, and still more preferably 20 mass % or more. The upper limit is preferably 80 mass % or less, more preferably 75 mass % or less, and still more preferably 70 mass % or less.

<<Resin>>

The photosensitive resin composition according to the embodiment of the present invention includes a resin. The resin is blended in, for example, an application for dispersing particles such as a pigment in a composition or an application as a binder. Mainly, a resin which is used for dispersing particles and the like in a composition is also referred to as a dispersant. However, such applications of the resin are merely exemplary, and the resin can also be used for other purposes in addition to such applications.

Examples of the resin include a (meth)acrylic resin, a (meth)acrylamide resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamide resin, a polyolefin resin, a cyclic olefin resin, a polyester resin, a styrene resin, a siloxane resin, a polyimine resin, and a polyurethane resin.

The weight-average molecular weight (Mw) of the resin is preferably 2000 to 2000000. The upper limit is preferably 1000000 or less and more preferably 500000 or less. The lower limit is preferably 3000 or more, more preferably 4000 or more, and still more preferably 5000 or more.

The photosensitive resin composition according to the embodiment of the present invention also preferably includes a resin having an amine value. According to this aspect, the pigment can be finely dispersed, and even in a case where fine pixels (patterns) are formed using the photosensitive resin composition, pixels (patterns) with few defects can be formed. The amine value of the above-described resin is preferably 25 to 60 mgKOH/g, more preferably 26 to 59 mgKOH/g, and still more preferably 27 to 58 mgKOH/g. The resin having an amine value is preferably used as a dispersant for the above-described specific phthalocyanine pigment.

From the viewpoint of achieving both the resolution of the photosensitive resin composition and the dispersibility of the pigment, the acid value of the resin having an amine value is preferably 0 to 250 mgKOH/g. The upper limit is preferably 200 mgKOH/g or less, and more preferably 150 mgKOH/g or less. From the reason that it is easy to improve the resolution by improving alkali solubility, the lower limit is preferably 5 mgKOH/g or more, and more preferably 10 mgKOH/g or more. In addition, the acid value of the resin having an amine value may be 0 mgKOH/g. In a case where the acid value of the resin having an amine value is 0 mgKOH/g, the effect of improving dispersion stability of the pigment can be obtained.

The number-average molecular weight of the resin having an amine value is preferably 500 to 50000 and more preferably 3000 to 30000.

Examples of the resin having an amine value include a (meth)acrylic resin, a polyimine resin, a polyester resin, a polyether resin, and a polyamide resin, and from the reason that transparency and heat resistance of the resin is good, a (meth)acrylic resin is preferable. Specific examples of a basic resin include copolymers of an N,N-di-substituted amino group-containing vinyl monomer, an alkyl (meth)acrylate monomer, and other vinyl monomers. Examples of the N,N-di-substituted amino group-containing vinyl monomer include N,N-dimethylaminoethyl (meth)acrylate, N,N-diethylaminoethyl (meth)acrylate, N,N-dimethylaminopropyl (meth)acrylate, N,N-diethylaminopropyl (meth)acrylate, N,N-dimethylaminoethyl (meth)acrylamide, and N,N-diethylaminoethyl (meth)acrylamide. Examples of the alkyl (meth)acrylate monomer include (meth)acrylic esters obtained by reacting an unsaturated monocarboxylic acid with an alkyl alcohol having 1 to 18 carbon atoms, such as methyl (meth)acrylate, ethyl (meth)acrylate, n-propyl (meth)acrylate, isopropyl (meth)acrylate, n-butyl (meth)acrylate, isobutyl (meth)acrylate, 2-ethylhexyl (meth)acrylate, cyclohexyl (meth)acrylate, stearyl (meth)acrylate, and lauryl (meth)acrylate. Examples of the other vinyl monomers include nitro group-containing vinyl monomers such as (meth)acrylonitrile; vinyl aromatic monomers such as styrene, α-methylstyrene, and benzyl (meth)acrylate; hydroxyl group-containing vinyl monomers such as 2-hydroxyethyl (meth)acrylate, hydroxypropyl (meth)acrylate, and polyethylene glycol (meth)acrylate; amide group-containing vinyl monomers such as (meth)acrylamide, N,N-dimethylacrylamide, N-isopropylacrylamide, and diacetoneacrylamide; vinyl monomers such as N-methylol (meth)acrylamide and dimethylol (meth)acrylamide; alkoxymethyl group-containing vinyl monomers such as N-methoxymethyl (meth)acrylamide and N-butoxymethyl (meth)acrylamide; olefins such as ethylene, propylene, and isoprene; dienes such as chloroprene and butadiene; vinyl ethers such as methyl vinyl ether, ethyl vinyl ether, n-propyl vinyl ether, isopropyl vinyl ether, n-butyl vinyl ether, and isobutyl vinyl ether; and fatty acid vinyls such as vinyl acetate and vinyl propionate.

Examples of a commercially available product of the resin having an amine value include DISPERBYK 161, 162, 163, 164, 166, 167, 168, 174, 182, 183, 184, 185, 2000, 2001, 2050, 2150, 2163, 2164, and BYK-LPN 6919 (all of which are manufactured by BYK Chemie Japan), SOLSPERSE 11200, 13240, 13650, 13940, 24000, 26000, 28000, 32000, 32500, 32550, 32600, 33000, 34750, 35100, 35200, 37500, 38500, 39000, 53095, 56000, and 7100 (all of which are manufactured by Lubrizol Japan Ltd.), and Efka PX 4300, 4330, 4046, 4060, and 4080 (all of which are manufactured by BASF).

The photosensitive resin composition according to the embodiment of the present invention preferably includes an alkali-soluble resin. In a case where the photosensitive resin composition according to the embodiment of the present invention includes an alkali-soluble resin, developability of the photosensitive resin composition is improved, and in a case where a pattern is formed by a photolithography method using the photosensitive resin composition according to the embodiment of the present invention, generation of development residue and the like can be effectively suppressed. Examples of the alkali-soluble resin include resins having an acid group. Examples of the acid group include a carboxyl group, a phosphoric acid group, a sulfo group, and a phenolic hydroxy group, and a carboxyl group is preferable. The acid group included in the alkali-soluble resin may be used singly or in combination of two or more kinds thereof. The alkali-soluble resin can also be used as a dispersant.

The alkali-soluble resin preferably includes a repeating unit having an acid group in the side chain, and more preferably includes 5% to 70% by mole of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

The alkali-soluble resin is also preferably an alkali-soluble resin having a polymerizable group. Examples of the polymerizable group include a (meth)allyl group and a (meth)acryloyl group. The alkali-soluble resin having a polymerizable group is preferably a resin including a repeating unit having a polymerizable group in the side chain and a repeating unit having an acid group in the side chain.

It is also preferable that the alkali-soluble resin includes a repeating unit derived from a monomer component including a compound represented by Formula (ED1) and/or a compound represented by Formula (ED2) (hereinafter, these compounds may be referred to as an “ether dimer”).

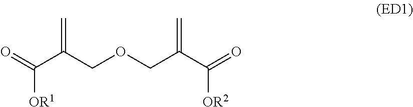

In Formula (ED1), R¹ and R² each independently represent a hydrogen atom or a hydrocarbon group having 1 to 25 carbon atoms, which may have a substituent.

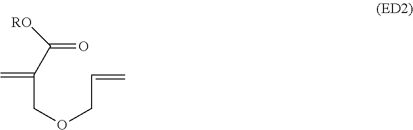

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

With regard to the alkali-soluble resin, reference can be made to the description in paragraph Nos. 0558 to 0571 of JP2012-208494A (paragraph Nos. 0685 to 0700 of the corresponding US2012/0235099A), the description in paragraph Nos. 0076 to 0099 of JP2012-198408A, and the description of JP2018-105911A, the contents of which are incorporated herein by reference.

The acid value of the alkali-soluble resin is preferably 30 to 500 mgKOH/g. The lower limit is preferably 50 mgKOH/g or more and more preferably 70 mgKOH/g or more. The upper limit is preferably 400 mgKOH/g or less, more preferably 300 mgKOH/g or less, and still more preferably 200 mgKOH/g or less.

As the photosensitive resin composition according to the embodiment of the present invention, a resin having a maleimide structure can also be used as the resin. In the present specification, the maleimide structure is a structure derived from a maleimide compound. Examples of the maleimide compound include maleimide and N-substituted maleimide. Examples of the N-substituted maleimide include cyclohexylmaleimide, phenylmaleimide, methylmaleimide, ethylmaleimide, n-butylmaleimide, and laurylmaleimide.

The resin having a maleimide structure is preferably a resin including a repeating unit having a maleimide structure. The maleimide structure may be included in the main chain of the repeating unit, or in the side chain of the repeating unit. From the reason that it is easy to form a cured film with suppressed color unevenness, it is preferable that the maleimide structure is included in the main chain of the repeating unit.

The photosensitive resin composition according to the embodiment of the present invention also preferably contains, as the resin, a resin i (hereinafter, also referred to as a resin i) including a repeating unit (hereinafter, also referred to as a repeating unit it-1) derived from a compound represented by Formula (I). In a case where the photosensitive resin composition according to the embodiment of the present invention includes the resin i, it is easy to obtain a cured film with suppressed color unevenness. The content of the repeating unit it-1 in total repeating units of the resin i is preferably 5 mol % or more, more preferably 10 mol % or more, and still more preferably 15 mol % or more.

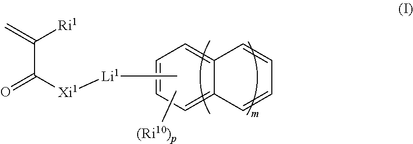

In the formula, Xi¹ represents O or NH, and O is preferable.

Ri¹ represents a hydrogen atom or a methyl group.

Li¹ represents a divalent linking group. Examples of the divalent linking group include a hydrocarbon group, a heterocyclic group, —NH—, —SO—, SO₂—, —CO—, —O—, —COO—, —OCO—, —S—, and a group formed by a combination of two or more of these groups. Examples of the hydrocarbon group include an alkyl group and an aryl group. The heterocyclic group may be a non-aromatic heterocyclic group or an aromatic heterocyclic group. The heterocyclic group is preferably a 5-membered ring or a 6-membered ring. Examples of the kind of the heteroatom constituting the heterocyclic group include a nitrogen atom, an oxygen atom, and a sulfur atom. The number of heteroatoms constituting the heterocyclic group is preferably 1 to 3. The heterocyclic group may be a single ring or a fused ring. The hydrocarbon group and heterocyclic group may have a substituent. Examples of the substituent include an alkyl group, an aryl group, a hydroxy group, and a halogen atom.

Ri¹⁰ represents a substituent. Examples of the substituent represented by Ri¹⁰ include the substituent Ti shown below, and the substituent represented by Ri¹⁰ is preferably a hydrocarbon group and more preferably an alkyl group which may have an aryl group as a substituent.

m represents an integer of 0 to 2, and is preferably 0 or 1 and more preferably 0. p represents an integer of 0 or more, preferably 0 to 4, more preferably 0 to 3, still more preferably 0 to 2, even more preferably 0 or 1, and particularly preferably 1.

(Substituent Ti)

Examples of a substituent Ti include a halogen atom, a cyano group, a nitro group, a hydrocarbon group, a heterocyclic group, —ORti¹, —CORti¹, —COORti¹, —OCORti¹, —NRti¹Rti², —NHCORti¹, —CONRti¹Rti², —NHCONRti¹Rti², —NHCOORti¹, —SRti¹, —SO₂Rti¹, —SO₂ORti¹, —NHSO₂Rti¹, and —SO₂NRti¹Rti². Rti¹ and Rti² each independently represent a hydrogen atom, a hydrocarbon group, or a heterocyclic group. Rti¹ and Rti² may be bonded to each other to form a ring.

Examples of the halogen atom include a fluorine atom, a chlorine atom, a bromine atom, and an iodine atom.

Examples of the hydrocarbon group include an alkyl group, an alkenyl group, an alkynyl group, and an aryl group. The number of carbon atoms in the alkyl group is preferably 1 to 30, more preferably 1 to 15, and still more preferably 1 to 8. The alkyl group may be linear, branched, or cyclic, and is preferably linear or branched and more preferably branched.

The number of carbon atoms in the alkenyl group is preferably 2 to 30, more preferably 2 to 12, and particularly preferably 2 to 8. The alkenyl group may be linear, branched, or cyclic, and is preferably linear or branched.

The number of carbon atoms of the alkynyl group is preferably 2 to 30 and more preferably 2 to 25. The alkynyl group may be linear, branched, or cyclic, and is preferably linear or branched.

The number of carbon atoms in the aryl group is preferably 6 to 30, more preferably 6 to 20, and still more preferably 6 to 12.

The heterocyclic group may be a single ring or a fused ring. The heterocyclic group is preferably a single ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The hydrocarbon group and the heterocyclic group may have a substituent or may be unsubstituted. Examples of the substituent include the substituents described in the substituent Ti.

The compound represented by Formula (I) is preferably a compound represented by Formula (I-1).

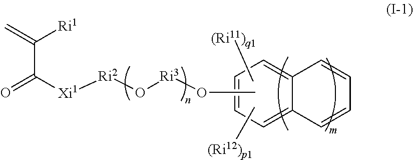

Xi¹ represents O or NH, and O is preferable.

Ri¹ represents a hydrogen atom or a methyl group.

Ri², Ri³, and Ri¹¹ each independently represent a hydrocarbon group.

The hydrocarbon group represented by Ri² and Ri³ is preferably an alkylene group or an arylene group, and more preferably an alkylene group. The number of carbon atoms in the alkylene group is preferably 1 to 10, more preferably 1 to 5, still more preferably 1 to 3, and particularly preferably 2 or 3. The hydrocarbon group represented by Ri¹¹ is preferably an alkyl group which may have an aryl group as a substituent, and more preferably an alkyl group having an aryl group as a substituent. The number of carbon atoms in the alkyl group is preferably 1 to 20, more preferably 1 to 10, and still more preferably 1 to 5. The number of carbon atoms in the alkyl group in a case where the alkyl group has an aryl group as a substituent means the number of carbon atoms in an alkyl moiety.

Ri¹² represents a substituent. Examples of the substituent represented by Ri¹² include the above-described substituent Ti.

n represents an integer of 0 to 15, and is preferably an integer of 0 or 5, more preferably an integer of 0 to 4, and still more preferably an integer of 0 to 3.

m represents an integer of 0 to 2, preferably 0 or 1 and more preferably 0.

p1 represents an integer of 0 or more, preferably 0 to 4, more preferably 0 to 3, still more preferably 0 to 2, even more preferably 0 or 1, and particularly preferably 0.

q1 represents an integer of 1 or more, preferably 1 to 4, more preferably 1 to 3, still more preferably 1 to 2, and particularly preferably 1.

The compound represented by Formula (I) is preferably a compound represented by Formula (III).

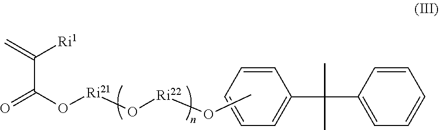

In the formula, Ri¹ represents a hydrogen atom or a methyl group, 2Ri²¹ and Ri²² each independently represent an alkylene group, and n represents an integer of 0 to 15. The number of carbon atoms in the alkylene group represented by Ri²¹ and Ri²² is preferably 1 to 10, more preferably 1 to 5, still more preferably 1 to 3, and particularly preferably 2 or 3. n is preferably an integer of 0 or 5, more preferably an integer of 0 to 4, and still more preferably an integer of 0 to 3.

Examples of the compound represented by Formula (I) include ethylene oxide- or propylene oxide-modified (meth)acrylate of para-cumylphenol. Examples of a commercially available product thereof include ARONIX M-110 (manufactured by TOAGOSEI CO., LTD.).

It is preferable that the resin i further includes a repeating unit (hereinafter, also referred to as a repeating unit it-2) derived from an alkyl (meth)acrylate. In a case where the resin i further has the repeating unit it-2, the effect of improving solubility of the photosensitive resin composition in a solvent is obtained. The number of carbon atoms in an alkyl moiety of the alkyl (meth)acrylate is preferably 3 to 10, more preferably 3 to 8, and still more preferably 3 to 6. Preferred specific examples of the alkyl (meth)acrylate include n-butyl (meth)acrylate, ethyl (meth)acrylate, and 2-ethylhexyl acrylate. From the reason that it is easy to obtain more excellent solubility in a solvent, n-butyl (meth)acrylate is preferable. The content of the repeating unit it-2 in total repeating units of the resin i is preferably 5 mol % or more, more preferably 10 mol % or more, and still more preferably 15 mol % or more.

It is also preferable that the resin i further includes a repeating unit having an acid group. According to this aspect, the effect of improving developability of the photosensitive resin composition is obtained. The content of the repeating unit having an acid group in total repeating units of the resin i is preferably 5 mol % or more, more preferably 10 mol % or more, and still more preferably 15 mol % or more. The upper limit is preferably 60 mol % or less and more preferably 50 mol % or less. The resin i including the repeating unit having an acid group is also the alkali-soluble resin.

It is also preferable that the resin i further includes a repeating unit having an ethylenically unsaturated bond-containing group. The content of the repeating unit having an ethylenically unsaturated bond-containing group in total repeating units of the resin i is preferably 5 mol % or more, more preferably 10 mol % or more, and still more preferably 15 mol % or more. The upper limit is preferably 50 mol % or less and more preferably 40 mol % or less.

The photosensitive resin composition according to the embodiment of the present invention also preferably includes a resin (hereinafter, also referred to as a resin Ac) having an aromatic carboxyl group. By using the resin Ac, it is possible to form a cured film which does not easily lose color of the pigment during development and has excellent developability.

The resin Ac may include the aromatic carboxyl group in the main chain of the repeating unit, or in the side chain of the repeating unit. From the reason that the effects described above can be easily obtained more remarkably, it is preferable that the aromatic carboxyl group is included in the main chain of the repeating unit. The details are not clear, but it is presumed that the presence of the aromatic carboxyl group near the main chain further improves these properties. In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin Ac is preferably a resin including at least one repeating unit selected from a repeating unit represented by Formula (b-1) or a repeating unit represented by Formula (b-10).

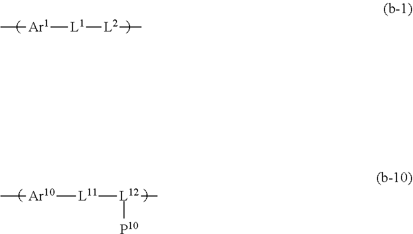

In Formula (b-1), Ar¹ represents a group including an aromatic carboxyl group, L¹ represents —COO— or —CONH—, and L² represents a divalent linking group.

In Formula (b-10), Ar¹⁰ represents a group including an aromatic carboxyl group, L¹¹ represents —COO— or —CONH—, L¹² represents a trivalent linking group, and P¹⁰ represents a polymer chain.

First, Formula (b-1) will be described. In Formula (b-1), examples of the group including an aromatic carboxyl group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

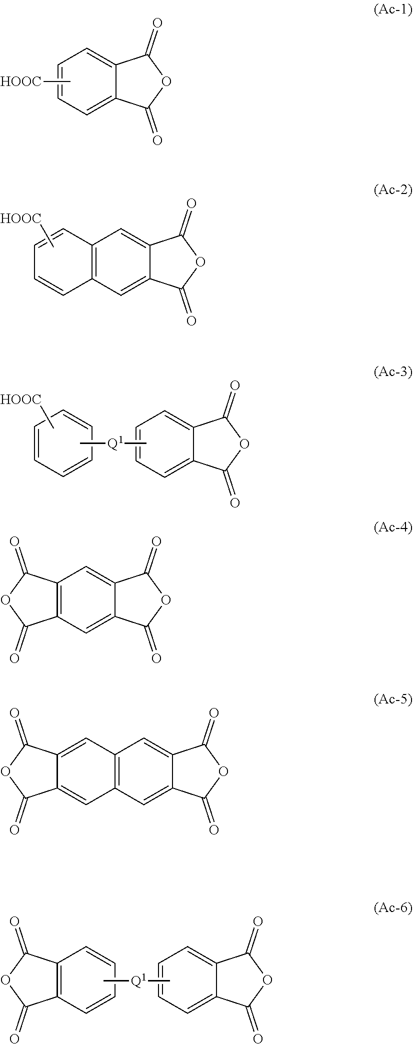

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

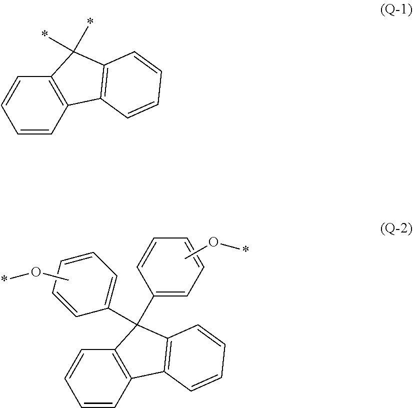

Specific examples of the group including an aromatic carboxyl group represented by Ar¹ include a group represented by Formula (Ar-1), a group represented by Formula (Ar-2), and a group represented by Formula (Ar-3).

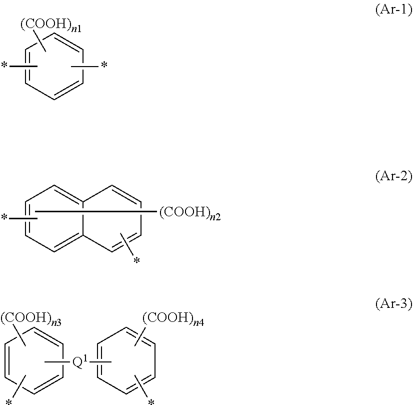

In Formula (Ar-1), n1 represents an integer of 1 to 4, and is preferably 1 or 2 and more preferably 2.

In Formula (Ar-2), n2 represents an integer of 1 to 8, and is preferably an integer of 1 or 4, more preferably 1 or 2, and still more preferably 2.

In Formula (Ar-3), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-3), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formula (b-1), L¹ represents —COO— or —CONH—, preferably —COO—.

In Formula (b-1), examples of the divalent linking group represented by L² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by —O-L^{2a}-O—. Examples of L^{2a} include an alkylene group; an arylene group; a group formed by a combination of an alkylene group and an arylene group; and a group formed by a combination of at least one selected from an alkylene group or an arylene group, and at least one selected from —O—, —CO—, —COO—, —OCO—, —NH—, or —S—. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

Next, Formula (b-10) will be described. In Formula (b-10), the group including an aromatic carboxyl group, represented by Ar¹⁰, has the same meaning as Ar¹ in Formula (b-1), and the preferred range is also the same.

In Formula (b-10), L¹¹ represents —COO— or —CONH—, preferably —COO—.

In Formula (b-10), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group. The trivalent linking group represented by L¹² is preferably a group represented by Formula (L12-1), and more preferably a group represented by Formula (L12-2).

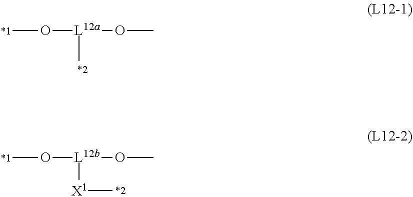

L^{12a} and L^{12b} each represent a trivalent linking group, X¹ represents S, *1 represents a bonding position with L¹¹ in Formula (b-10), and *2 represents a bonding position with P¹⁰ in Formula (b-10).

Examples of the trivalent linking group represented by L^{12a} and L^{12b} include a hydrocarbon group; and a group formed by a combination of a hydrocarbon group and at least one selected from —O—, —CO—, —COO—, —OCO—, —NH—, or —S—.

In Formula (b-10), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. The weight-average molecular weight of the polymer chain P¹⁰ is preferably 500 to 20000. The lower limit is preferably 1000 or more. The upper limit is preferably 10000 or less, more preferably 5000 or less, and still more preferably 3000 or less. In a case where the weight-average molecular weight of P¹⁰ is within the above-described range, dispersibility of the pigment in the composition is good. In a case where the resin having an aromatic carboxyl group is a resin having the repeating unit represented by Formula (b-10), this resin is preferably used as a dispersant.

As the photosensitive resin composition according to the embodiment of the present invention, it is preferable to use a resin (hereinafter, also referred to as a resin OP) having a structure represented by Formula (OP1). This resin is preferably used as a dispersant.

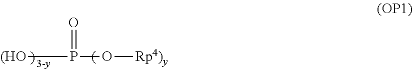

In the formula, Rp⁴ represents a polyether residue and/or polyester residue having a number-average molecular weight of 400 to 30000 and having an ethylenically unsaturated bond-containing group, and y represents a number of 1 or 2.

The number-average molecular weight of Rp⁴ is more preferably 400 to 10000, and still more preferably 400 to 3000. In a case where the number-average molecular weight of Rp⁴ is within the above-described range, the dispersibility of the pigment is good, and such a resin is preferably used as a dispersant.

Examples of the polyether residue and/or polyester residue having an ethylenically unsaturated bond-containing group represented by Rp⁴ include a polyether residue and/or polyester residue having a styrene group, a (meth)acryloyl group, a cyanoacryloyl group, a vinyl ether group, or the like.

Rp⁴ is preferably a group represented by Formula (Rp-1).

—Rp¹²-O—Rp¹³-(O—Rp¹⁴)ₛ

In the formula, Rp¹² represents an alkylene group, Rp¹³ represents a trihydric or higher polyhydric alcohol residue, Rp¹⁴ represents a (meth)acryloyl group or a cyanoacryloyl group, and s represents 2 or more.

Rp¹² is preferably an alkylene group having 8 or less carbon atoms. In addition, from the viewpoint of pigment dispersibility, s is preferably 2 or more. In this case, as Rp¹⁴, different groups may be used. s is still more preferably 2 to 5, and particularly preferably 2.

Examples of the trihydric or higher polyhydric alcohol represented by Rp¹³ include glycerin, propyl alcohol, pentaerythritol, and dipentaerythritol. In particular, a trihydric to hexahydric alcohol is preferable.

As the resin OP, a phosphoric acid ester having a single type of Rp⁴ may be used, or a plurality of types of phosphoric acid esters consisting of different Rp⁴ may be used. In addition, the resin OP may be only a resin in which y in Formula (OP1) is 1, or may be a mixture of a resin in which y in Formula (OP1) is 1 and a resin in which y in Formula (OP1) is 2. In addition, in a case where Rp⁴ of the compound represented by Formula (OP1) is a polycaprolactone residue having a number-average molecular weight of 400 to 10000 (more preferably, 400 to 3000), the pigment dispersibility is improved, which is preferable.

The photosensitive resin composition according to the embodiment of the present invention can contain a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group is 70 mol % or more in a case where the total amount of the acid group and the basic group is 100 mol %. The acid group included in the acidic dispersant (acidic resin) is preferably a carboxyl group. The acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

It is also preferable that the resin used as a dispersant is the above-described resin having an amine value.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

It is also preferable that the resin used as a dispersant are a resin including a repeating unit having an ethylenically unsaturated bond-containing group in the side chain. The content of the repeating unit having an ethylenically unsaturated bond-containing group in the side chain is preferably 10 mol % or more, more preferably 10 to 80 mol %, and still more preferably 20 to 70 mol % with respect to the total repeating units of the resin. In addition, as the dispersant, a resin described in JP2018-087939A can also be used.

A commercially available product is also available as the dispersant, and specific examples thereof include DISPERBYK series manufactured by BYK Chemie Japan, Solsperse series manufactured by Lubrizol Japan Ltd., Efka series manufactured by BASF, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

The content of the resin in the total solid content of the photosensitive resin composition is preferably 10 to 50 mass %. The upper limit is preferably 40 mass % or less and more preferably 30 mass % or less. The lower limit is preferably 15 mass % or more and more preferably 20 mass % or more.

In addition, the content of the alkali-soluble resin in the resin included in the photosensitive resin composition according to the embodiment of the present invention is preferably 10 to 100 mass %, more preferably 20 to 100 mass %, and still more preferably 30 to 100 mass %.

In addition, the content of the resin having an amine value in the resin included in the photosensitive resin composition according to the embodiment of the present invention is preferably 0 to 100 mass %. The upper limit is preferably 90 mass % or less and more preferably 80 mass % or less. The lower limit is preferably 10 mass % or more and more preferably 20 mass % or more.

In addition, in a case where the photosensitive resin composition according to the embodiment of the present invention includes a dispersant as a resin, the content of the dispersant is preferably 10 to 100 parts by mass with respect to 100 parts by mass of the specific phthalocyanine pigment. The upper limit is preferably 80 parts by mass or less and more preferably 60 parts by mass or less. The lower limit is preferably 20 parts by mass or more and still more preferably 30 parts by mass or more. In addition, the content of the resin having an amine value in the dispersant is preferably 0 to 100 mass %, more preferably 10 to 100 mass %, and still more preferably 20 to 100 mass %. In addition, the content of the dispersant in the resin is preferably 10 to 100 mass %. The upper limit is preferably 95 mass % or less and more preferably 90 mass % or less. The lower limit is preferably 20 mass % or more and more preferably 30 mass % or more.

<<Polymerizable Compound>>

The photosensitive resin composition according to the embodiment of the present invention contains a polymerizable compound. As the polymerizable compound, a known compound which is cross-linkable by a radical, an acid, or heat can be used. In the present invention, the polymerizable compound is preferably, for example, a compound having an ethylenically unsaturated bond-containing group. Examples of the ethylenically unsaturated bond-containing group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is preferably 2000 or less, more preferably 1500 or less, and still more preferably 1000 or less. The lower limit is preferably 150 or more and more preferably 250 or more.

From the viewpoint of temporal stability of the photosensitive resin composition and light resistance and the like of the cured film to be obtained, an ethylenically unsaturated bond-containing group (hereinafter, referred to as a C═C value) of a monomer-type polymerizable compound is preferably 2 to 14 mmol/g. The lower limit is preferably 3 mmol/g or more, more preferably 4 mmol/g or more, and still more preferably 5 mmol/g or more. The upper limit is preferably 12 mmol/g or less, more preferably 10 mmol/g or less, and still more preferably 8 mmol/g or less. The C═C value of the ethylenically unsaturated bond-containing group is obtained by dividing the number of ethylenically unsaturated bond-containing groups included in one molecule of the polymerizable compound by the molecular weight of the polymerizable compound.

The polymerizable compound is preferably a compound including 3 or more ethylenically unsaturated bond-containing groups, more preferably a compound including 3 to 15 ethylenically unsaturated bond-containing groups, and still more preferably a compound having 3 to 6 ethylenically unsaturated bond-containing groups. In addition, the polymerizable compound is preferably a trifunctional to pentadecafunctional (meth)acrylate compound and more preferably a trifunctional to hexafunctional (meth)acrylate compound. Specific examples of the polymerizable compound include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, JP6031807B, and JP2017-194662A, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which the (meth)acryloyl group of these compounds is bonded through an ethylene glycol and/or a propylene glycol residue (for example, SR454 and SR499 which are commercially available from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a polymerizable compound having an acid group can also be used. By using a polymerizable compound having an acid group, the polymerizable compound in a non-exposed portion is easily removed during development and the generation of the development residue can be suppressed. Examples of the acid group include a carboxyl group, a sulfo group, and a phosphoric acid group, and a carboxyl group is preferable. Examples of a commercially available product of the polymerizable compound having an acid group include ARONIX M-305, M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

As the polymerizable compound, a polymerizable compound having a caprolactone structure can also be used. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having four ethyleneoxy groups, and KAYARAD TPA-330 manufactured by Nippon Kayaku Co., Ltd, which is a trifunctional (meth)acrylate having three isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the polymerizable compounds having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-3061, AH-600, T-600, AI-600, and LINC-202UA (manufactured by KYOEISHA CHEMICAL Co., Ltd.) can also be used.

The content of the polymerizable compound in the total solid content of the photosensitive resin composition is preferably 0.1 to 50 mass %. The lower limit is more preferably 0.5 mass % or more and still more preferably 1 mass % or more. The upper limit is more preferably 45 mass % or less and still more preferably 40 mass % or less. The polymerizable compound may be used singly or in combination of two or more kinds thereof. In a case where two or more kinds thereof are used in combination, the total thereof is preferably within the above-described range.

<<Photopolymerization Initiator>>

The photosensitive resin composition according to the embodiment of the present invention contains a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. Examples of the photopolymerization initiator include compounds described in paragraphs 0065 to 0111 of JP2014-130173A, and JP6301489B, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A.

An oxime compound having a nitro group can be used as the photopolymerization initiator. It is preferable that the oxime compound having a nitro group is a dimer. Specific examples of the oxime compound having a nitro group include a compound described in paragraph Nos. 0031 to 0047 of JP2013-114249A and paragraph Nos. 0008 to 0012 and 0070 to 0079 of JP2014-137466A, a compound described in paragraph Nos. 0007 to 0025 of JP4223071B, and ADEKAARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

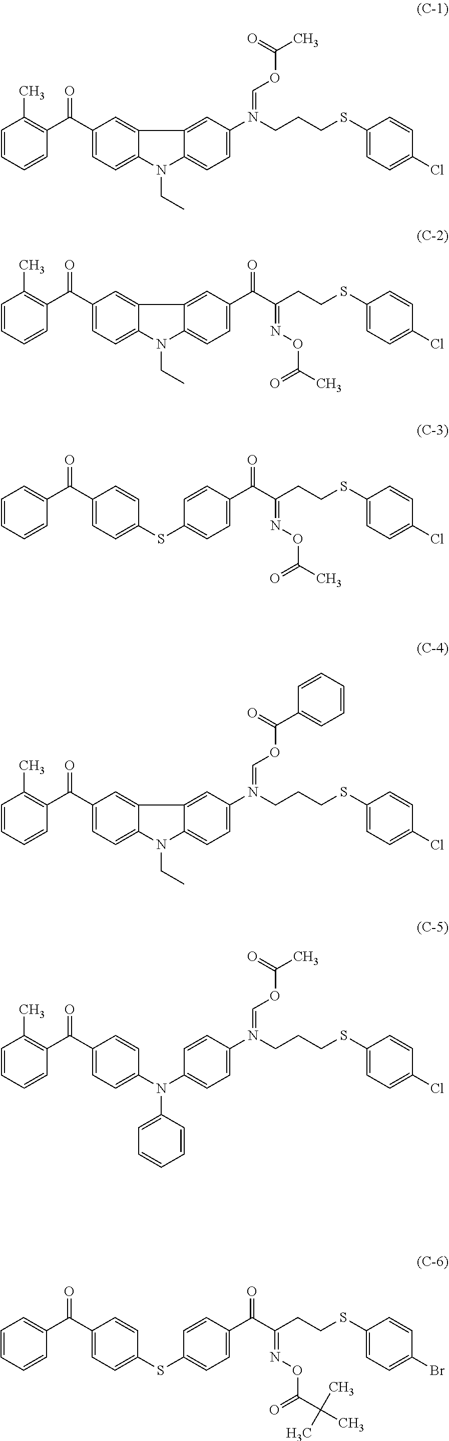

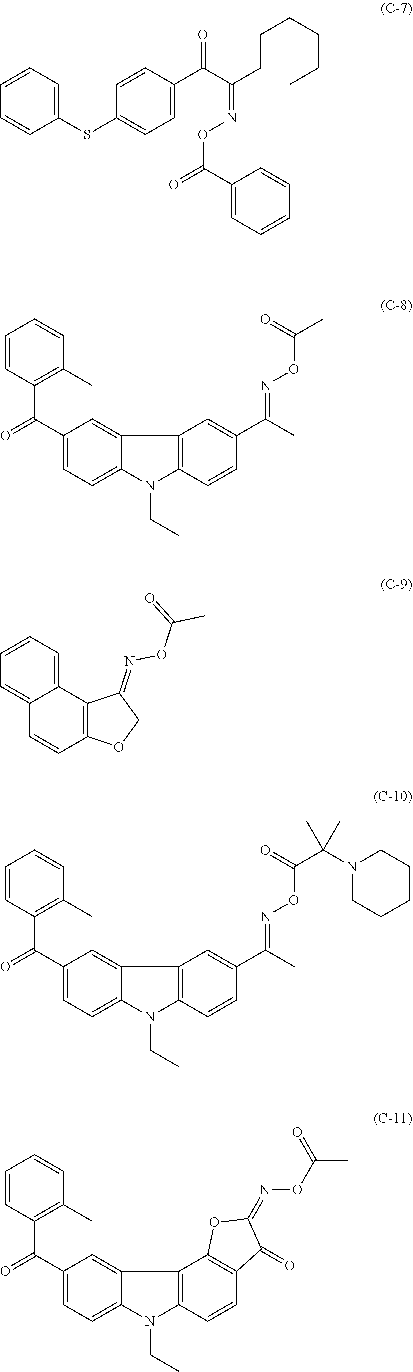 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

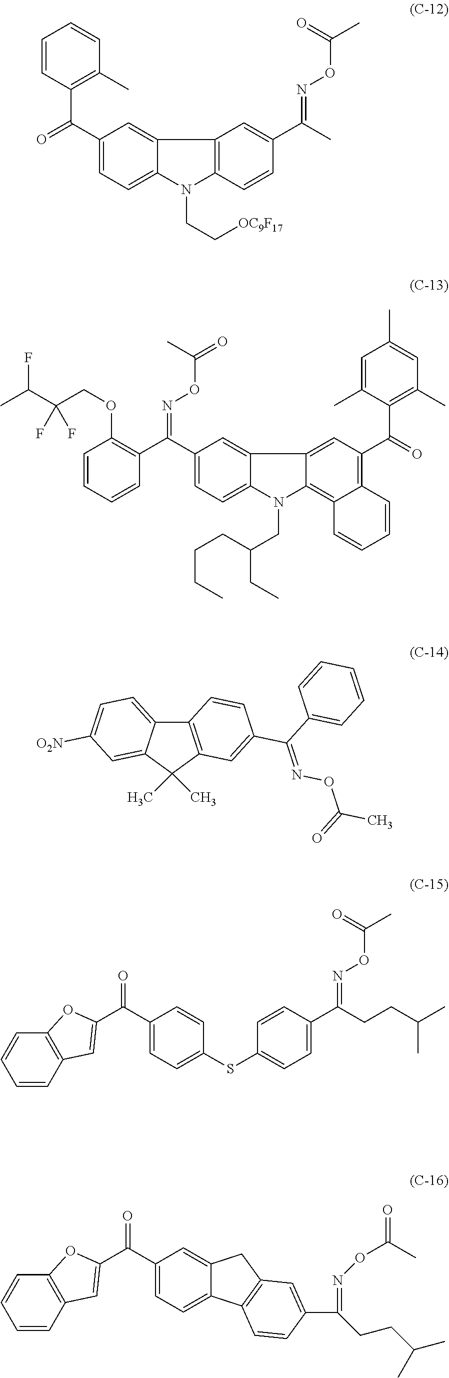

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate at a concentration of 0.01 g/L.

As the photopolymerization initiator, a bifunctional or tri- or more functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or more functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime compound described in JP6469669B.

The content of the photopolymerization initiator in the total solid content of the photosensitive resin composition is preferably 0.1 to 30 mass %. The lower limit is preferably 0.5 mass % or more and more preferably 1 mass % or more. The upper limit is preferably 20 mass % or less and more preferably 15 mass % or less. The photopolymerization initiator may be used singly or in combination of two or more kinds thereof. In a case where two or more kinds thereof are used in combination, the total thereof is preferably within the above-described range.

<<Ultraviolet Absorber>>

The photosensitive resin composition according to the embodiment of the present invention contains an ultraviolet absorber. The ultraviolet absorber is preferably a compound having a maximal absorption wavelength in a wavelength range of 300 to 380 nm and more preferably a compound having a maximal absorption wavelength in a wavelength range of 320 to 380 nm. In addition, the molar absorption coefficient of the ultraviolet absorber at a wavelength of 365 nm is preferably 5000 L·mol⁻¹·cm⁻¹ or more, more preferably 10000 L·mol⁻¹·cm⁻¹ or more, and still more preferably 30000 L·mol⁻¹·cm⁻¹ or more. The upper limit is preferably, for example, 100000 L·mol⁻¹·cm⁻¹ or less.

Examples of the ultraviolet absorber include a conjugated diene compound, a methyldibenzoyl compound, a triazine compound, a benzotriazole compound, a benzophenone compound, a salicylate compound, a coumarin compound, an acrylonitrile compound, a benzodithiazole compound, a cinnamic acid compound, α-β unsaturated ketone, and a carbostyryl compound, and from the reason that it is easy to obtain more excellent light resistance, a conjugated diene compound, a benzotriazole compound, or a triazine compound is preferable.

The conjugated diene compound is preferably a compound represented by Formula (UV-1).

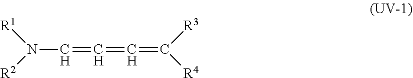

In Formula (UV-1), R¹ and R² each independently represent a hydrogen atom, an alkyl group having 1 to 20 carbon atoms, or an aryl group having 6 to 20 carbon atoms, and R¹ and R² may be the same or different from each other. However, at least one of R¹ or R² is an alkyl group having 1 to 20 carbon atoms or an aryl group having 6 to 20 carbon atoms. R¹ and R² may form a cyclic amino group together with a nitrogen atom to which R¹ and R² are bonded. Examples of the cyclic amino group include a piperidino group, a morpholino group, a pyrrolidino group, a hexahydroazepino group, and a piperazino group. R¹ and R² each independently preferably an alkyl group having 1 to 20 carbon atoms, more preferably an alkyl group having 1 to 10 carbon atoms, and still more preferably an alkyl group having 1 to 5 carbon atoms.

In Formula (UV-1), R³ and R⁴ each independently represent an electron withdrawing group. R³ and R⁴ are each independently preferably an acyl group, a carbamoyl group, an alkyloxycarbonyl group, an aryloxycarbonyl group, a cyano group, a nitro group, an alkylsulfonyl group, an arylsulfonyl group, a sulfonyloxy group, or a sulfamoyl group, and more preferably an acyl group, a carbamoyl group, an alkyloxycarbonyl group, an aryloxycarbonyl group, a cyano group, an alkylsulfonyl group, an arylsulfonyl group, a sulfonyloxy group, or a sulfamoyl group. In addition, R³ and R⁴ may be bonded to each other to form a cyclic electron withdrawing group. Examples of the cyclic electron withdrawing group formed by bonding R³ and R⁴ to each other include a 6-membered ring including two carbonyl groups.

At least one of R¹, R², R³, or R⁴ in Formula (UV-1) may be in a form of a polymer derived from a monomer bonded to a vinyl group through a linking group. It may be a copolymer with another monomer.

The description of the substituent of the ultraviolet absorber represented by Formula (UV-1) can be found in paragraph Nos. 0024 to 0033 of JP2009-265642A, the content of which is incorporated herein by reference. Specific examples of the ultraviolet absorber represented by Formula (UV-1) include compounds having the following structures and compounds described in paragraph Nos. 0034 to 0036 of JP2009-265642A. In addition, examples of a commercially available product of the ultraviolet absorber represented by Formula (UV-1) include UV-503 (manufactured by Daito Chemical Co., Ltd.).

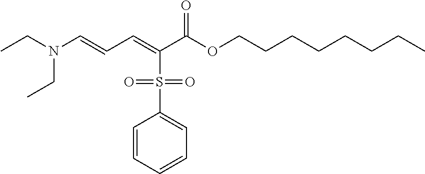 [SMILES: CCCCCCCCOC(=O)/C(=C/C=C/N(CC)CC)S(=O)(=O)c1ccccc1]

The methyldibenzoyl compound is preferably a compound represented by Formula (UV-2).

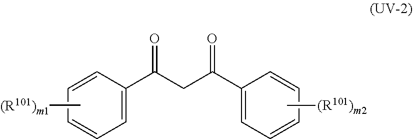

In Formula (UV-2), R¹⁰¹ and R¹⁰² each independently represent a substituent, and m1 and m2 each independently represent 0 to 4.

Examples of the substituent represented by R¹⁰¹ and R¹⁰² include a halogen atom, a cyano group, a nitro group, an alkyl group, an aryl group, a heteroaryl group, an alkoxy group, an aryloxy group, a heteroaryloxy group, an alkylthio group, an arylthio group, a heteroarylthio group, —NR^{U1}R^{U2}, —COR^{U3}, —COOR^{U4}, —OCOR^{U5}, —NHCOR^{U6}, —CONR^{U7}R^{U8}, —NHCONR^{U9}R^{U10}, —NHCOOR^{U11}, —SO₂R^{U12}, —SO₂OR^{U13}, —NHSO₂R^{U14}, and —SO₂NR^{U15}R^{U16}. R^{U1} to R^{U16} each independently represent a hydrogen atom, an alkyl group having 1 to 8 carbon atoms, or an aryl group.

It is preferable that the substituents represented by R¹⁰¹ and R¹⁰² are each independently an alkyl group or an alkoxy group. The number of carbon atoms in the alkyl group is preferably 1 to 20 and more preferably 1 to 10. Examples of the alkyl group include a linear alkyl group, a branched alkyl group, and a cyclic alkyl group, and a linear alkyl group or a branched alkyl group is preferable and a branched alkyl group is more preferable. The number of carbon atoms in the alkoxy group is preferably 1 to 20 and more preferably 1 to 10. The alkoxy group is preferably linear or branched, and more preferably branched.

In Formula (UV-2), a combination in which one of R¹⁰¹ or R¹⁰² is an alkyl group and the other is an alkoxy group is preferable.

m1 and m2 each independently represent 0 to 4. m1 and m2 are each independently preferably 0 to 2, more preferably 0 or 1, and particularly preferably 1.

Specific examples of the compound represented by Formula (UV-2) include avobenzone.

The triazine compound is preferably a compound represented by Formula (UV-3-1), (UV-3-2), or (UV-3-3).

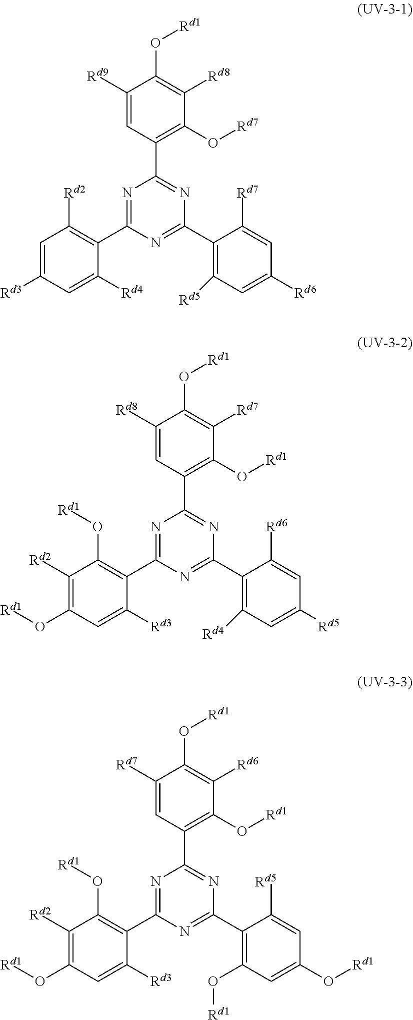

In the formulae, R^{d1}'s independently represent a hydrogen atom, an alkyl group having 1 to 15 carbon atoms, an alkenyl group having 3 to 8 carbon atoms, an aryl group having 6 to 18 carbon atoms, an alkylaryl group having 7 to 18 carbon atoms, or an arylalkyl group having 7 to 18 carbon atoms. The alkyl group, alkenyl group, aryl group, alkylaryl group, and arylalkyl group may have a substituent. Examples of the substituent include the groups described in the substituent Ti.

In the formulae, R^{d2} to R^{d9} independently represent a hydrogen atom, a halogen atom, a hydroxy group, an alkyl group having 1 to 15 carbon atoms, an alkenyl group having 3 to 8 carbon atoms, an aryl group having 6 to 18 carbon atoms, an alkylaryl group having 7 to 18 carbon atoms, or an arylalkyl group having 7 to 18 carbon atoms. The alkyl group, alkenyl group, aryl group, alkylaryl group, and arylalkyl group may have a substituent. Examples of the substituent include the groups described in the substituent Ti.

Specific examples of the triazine compound include mono(hydroxyphenyl)triazine compounds such as 2-[4-[(2-hydroxy-3-dodecyloxypropyl)oxy]-2-hydroxyphenyl]-4,6-bi s (2,4-dimethylphenyl)-1,3,5-triazine, 2-[4-[(2-hydroxy-3-tridecyloxypropyl)oxy]-2-hydroxyphenyl]-4,6-bis(2,4-dimethylphenyl)-1,3,5-triazine, and 2-(2,4-dihydroxyphenyl)-4,6-bis(2,4-dimethylphenyl)-1,3,5-triazine; bis(hydroxyphenyl)triazine compounds such as 2,4-bis(2-hydroxy-4-propyloxyphenyl)-6-(2,4-dimethylphenyl)-1,3,5-triazine, 2,4-bis(2-hydroxy-3-methyl-)4-propyloxyphenyl)-6-(4-methylphenyl)-1,3,5-triazine, and 2,4-bis(2-hydroxy-3-methyl-4-hexyloxyphenyl)-6-(2,4-dimethylphenyl)-1,3,5-triazine; and tris(hydroxyphenyl)triazine compounds such as 2,4-bis(2-hydroxy-4-butoxyphenyl)-6-(2,4-dibutoxyphenyl)-1,3,5-triazine, 2,4,6-tris(2-hydroxy-4-octyloxyphenyl)-1,3,5-triazine, and 2,4,6-tris[2-hydroxy-4-(3-butoxy-2-hydroxypropyloxy)phenyl]-1,3,5-triazine. Examples of a commercially available product of the triazine compound include TINUVIN 400, TINUVIN 405, TINUVIN 460, TINUVIN 477, and TINUVIN 479 (all of which are manufactured by BASF).

The benzotriazole compound is preferably a compound represented by Formula (UV-4).

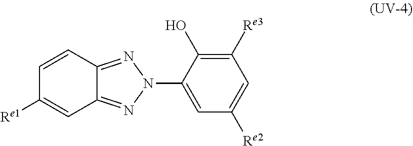

In the formula, R^{e1} to R^{e3} each independently represent a hydrogen atom, a halogen atom, a hydroxy group, an alkyl group having 1 to 9 carbon atoms, an alkoxy group having 1 to 9 carbon atoms, an alkylaryl group having 7 to 18 carbon atoms, or an arylalkyl group having 7 to 18 carbon atoms. The alkyl group, alkylaryl group, and arylalkyl group may have a substituent. Examples of the substituent include the groups described in the substituent Ti, and an alkoxycarbonyl group having 1 to 9 carbon atoms is preferable.

Specific examples of the benzotriazole compound include 2-(2′-hydroxy-3′,5′-di-tert-butylphenyl)-5-chlorobenzotriazole, 2-(2′-hydroxy-3′-tert-butyl-5′-methylphenyl)-5-chlorobenzotriazole, 2-(2′-hydroxy-3′-tert-amyl-5′-isobutylphenyl)-5-chlorobenzotriazole, 2-(2′-hydroxy-3′-isobutyl-5′-methylphenyl)-5-chlorobenzotriazole, 2-(2′-hydroxy-3′-isobutyl-5′-propylphenyl)-5-chlorobenzotriazole, 2-(2′-hydroxy-3′,5′-di-tert-butylphenyObenzotriazole, 2-(2′-hydroxy-5′-methylphenyl)benzotriazole, 2-[2′-hydroxy-5′-(1,1,3,3-tetramethyl)phenyl]benzotriazole, 2-(2-hydroxy-5-tert-butylphenyl)-2H-benzotriazole, 3-(2H-benzotriazol-2-yl)-5-(1,1-dimethylethyl)-4-hydroxy, 2-(2H-benzotriazol-2-yl)-4,6-(1-methyl-1-phenylethyl)phenol, and 2-(2H-benzotriazol-2-yl)-6-(1-methyl-1-phenylethyl)-4-(1,1,3,3-tetramethylbutyl)phenol. Examples of a commercially available product thereof include TINUVIN PS, TINUVIN 99-2, TINUVIN 109, TINUVIN 326, TINUVIN 328, TINUVIN 384-2, TINUVIN 900, TINUVIN 928, TINUVIN 171, and TINUVIN 1130 (all of which are manufactured by BASF). As the benzotriazole compound, MYUA series manufactured by Miyoshi Oil & Fat Co., Ltd. may be used.

Examples of the benzophenone compound include 2,2′-dihydroxy-4-methoxybenzophenone, 2,2′-dihydroxy-4,4′-dimethoxybenzophenone, 2,2′,4,4′-tetrahydroxybenzophenone, 2-hydroxy-4-methoxybenzophenone, 2,4-dihydroxybenzophenone, and 2-hydroxy-4-octoxybenzophenone. Examples of a commercially available product of the benzophenone compound include Uvinul A, Uvinul 3049, and Uvinul 3050 (all of which are manufactured by BASF).

Examples of the salicylate compound include phenyl salicylate, p-octylphenyl salicylate, and p-t-butylphenyl salicylate.

Examples of the coumarin compound include coumarin-4,4-hydroxycoumarin, and 7-hydroxycoumarin.

Examples of the acrylonitrile compound include ethyl 2-cyano-3,3-diphenylacrylate and 2-ethylhexyl 2-cyano-3,3-diphenylacrylate.

The content of the ultraviolet absorber in the total solid content of the photosensitive resin composition is 0.1 to 10 mass %. The upper limit is preferably 9.5 mass % or less and more preferably 9 mass % or less. The lower limit is preferably 0.5 mass % or more and more preferably 1 mass % or more. In a case where the content of the ultraviolet absorber is 0.1 mass % or more, light resistance of the cured film to be obtained can be improved. In addition, in a case where the content of the ultraviolet absorber is 10 mass % or less, it is possible to form a cured film in which the occurrence of color mixing with pixels of other hues is suppressed. Further, in a case of forming pixels by a photolithography method using the photosensitive resin composition, it is also possible to improve resolution of the photosensitive resin composition and form pixels having good rectangularity.

It is preferable that the photosensitive resin composition according to the embodiment of the present invention includes 1 to 200 parts by mass of the ultraviolet absorber with respect to 100 parts by mass of the photopolymerization initiator. According to this aspect, both resolution and light resistance can be achieved at a higher level. The upper limit of the above-described content of the ultraviolet absorber is preferably 190 parts by mass or less and more preferably 170 parts by mass or less. The lower limit is preferably 5 parts by mass or more and more preferably 10 parts by mass or more.

It is preferable that the photosensitive resin composition according to the embodiment of the present invention includes 0.1 to 100 parts by mass of the ultraviolet absorber with respect to 100 parts by mass of the polymerizable compound. According to this aspect, both resolution and light resistance can be achieved at a higher level. The upper limit of the above-described content of the ultraviolet absorber is preferably 80 parts by mass or less and more preferably 50 parts by mass or less. The lower limit is preferably 1 part by mass or more and more preferably 5 parts by mass or more.

The ultraviolet absorber included in the photosensitive resin composition according to the embodiment of the present invention may be used singly or in combination of two or more kinds thereof. In a case where the photosensitive resin composition according to the embodiment of the present invention includes two or more kinds of ultraviolet absorbers, the total thereof is within the above-described range.

<<Solvent>>

The photosensitive resin composition according to the embodiment of the present invention contains a solvent. Basically, the solvent is not particularly limited as long as it satisfies the solubility of the respective components and the application properties of the photosensitive resin composition. Examples of the solvent include an organic solvent. Examples of the organic solvent include an ester solvent, a ketone solvent, an alcohol solvent, an amide solvent, an ether solvent, and a hydrocarbon solvent. The details of the organic solvent can be found in paragraph No. 0223 of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

The content of the solvent in the photosensitive resin composition is preferably 10 to 95 mass %, more preferably 20 to 90 mass %, and still more preferably 30 to 90 mass %.

In addition, from the viewpoint of environmental regulation, it is preferable that the photosensitive resin composition according to the embodiment of the present invention does not substantially contain environmentally regulated substances. In the present invention, the description “does not substantially contain environmentally regulated substances” means that the content of the environmentally regulated substances in the photosensitive resin composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their amount used and handling method. These compounds can be used as a solvent in a case of producing respective components used in the photosensitive resin composition, and may be incorporated into the photosensitive resin composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause cross-linking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, photosensitive resin composition produced by mixing these compounds, or the like.

<<Pigment Derivative>>

The photosensitive resin composition according to the embodiment of the present invention can contain a pigment derivative. The pigment derivative is used as a dispersion aid for the pigment. Examples of the pigment derivative include a compound having a structure in which a part of a chromophore is substituted with an acid group or a basic group.

Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable.

Examples of the acid group included in the pigment derivative include a carboxyl group, a sulfo group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion.

Examples of the basic group included in the pigment derivative include an amino group, a pyridyl group, or a salt thereof, a salt of an ammonium group, and a phthalimidomethyl group. Examples of the amino group include —NH₂, a dialkylamino group, an alkylarylamino group, a diarylamino group, and a cyclic amino group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be used. The maximum value (εmax) of the molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in JP1981-118462A (JP-556-118462A), JP1988-264674A (JP-563-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

The content of the pigment derivative is preferably 1 to 30 parts by mass with respect to 100 parts by mass of the pigment. The lower limit is preferably 2 parts by mass or more and more preferably 3 parts by mass or more. The upper limit is preferably 25 parts by mass or less, more preferably 20 parts by mass or less, and still more preferably 15 parts by mass or less. The pigment derivative may be used singly or in combination of two or more kinds thereof. In a case where two or more kinds of pigment derivatives are used in combination, it is preferable that the total content of the two or more kinds of pigment derivatives is within the above-described range.

<<Compound Having Epoxy Group>>

The photosensitive resin composition according to the embodiment of the present invention can contain a compound having an epoxy group (hereinafter, also referred to as an epoxy compound). Examples of the epoxy compound include a compound having one or more epoxy groups in one molecule, and a compound having two or more epoxy groups in one molecule is preferable. The epoxy compound preferably has 1 to 100 epoxy groups in one molecule. The upper limit of the number of epoxy groups may be, for example, 10 or less or 5 or less. The lower limit of the number of epoxy groups is preferably 2 or more. As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of which are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). The weight-average molecular weight of the epoxy compound is preferably 200 to 100000 and more preferably 500 to 50000. The upper limit of the weight-average molecular weight is preferably 10000 or less, more preferably 5000 or less, and still more preferably 3000 or less.

Examples of a commercially available product of the epoxy compound include EHPE3150 (manufactured by Daicel Corporation) and EPICLON N-695 (manufactured by DIC Corporation).

The content of the epoxy compound in the total solid content of the photosensitive resin composition is preferably 0.1 to 20 mass %. The lower limit is, for example, preferably 0.5 mass % or more, and more preferably 1 mass % or more. The upper limit is, for example, preferably 15 mass % or less and still more preferably 10 mass % or less. The epoxy compound contained in the photosensitive resin composition may be only one kind or two or more kinds thereof. In a case of using two or more kinds thereof, the total content thereof is preferably within the above-described range.

<<Furyl Group-Containing Compound>>

The photosensitive resin composition according to the embodiment of the present invention preferably contains a compound (hereinafter, also referred to as a furyl group-containing compound) including a furyl group. According to this aspect, a photosensitive resin composition having excellent curing properties at a low temperature can be obtained.

The structure of the furyl group-containing compound is not particularly limited as long as the compound includes a furyl group (group obtained by removing one hydrogen atom from furan). As the furyl group-containing compound, compounds described in paragraph Nos. 0049 to 0089 of JP2017-194662A can be used. In addition, compounds described in JP2000-233581A, JP1994-271558A, JP1994-293830A, JP1996-239421A, JP1998-508655A, JP2000-001529A, JP2003-183348A, JP2006-193628A, JP2007-186684A, JP2010-265377A, JP2011-170069A, and the like can also be used.

The furyl group-containing compound may be a monomer or a polymer. From the reason that it is easy to improve durability of the cured film to be obtained, and the like, a polymer is preferable. In a case of a polymer, the weight-average molecular weight thereof is preferably 2000 to 70000. The upper limit is preferably 60000 or less and more preferably 50000 or less. The lower limit is preferably 3000 or more, more preferably 4000 or more, and still more preferably 5000 or more. The polymer-type furyl group-containing compound is also a component corresponding to the resin in the photosensitive resin composition according to the embodiment of the present invention.

Examples of the monomer-type furyl group-containing compound (hereinafter, also referred to as a furyl group-containing monomer) include a compound represented by Formula (fur-1).

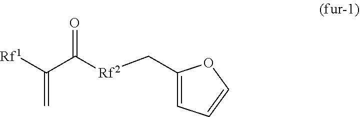

In the formula, Rf¹ represents a hydrogen atom or a methyl group, and Rf² represents a divalent linking group.

Examples of the divalent linking group represented by Rf² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group.

The furyl group-containing monomer is preferably a compound represented by Formula (fur-1-1).

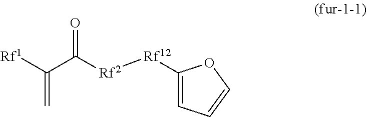

In the formula, Rf¹ represents a hydrogen atom or a methyl group, Rf¹¹ represents —O— or —NH—, and Rf¹² represents a single bond or a divalent linking group. Examples of the divalent linking group represented by Rf¹² include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group.

Specific examples of the furyl group-containing monomer include compounds having the following structures. In the structural formulae, Rf¹ represents a hydrogen atom or a methyl group.

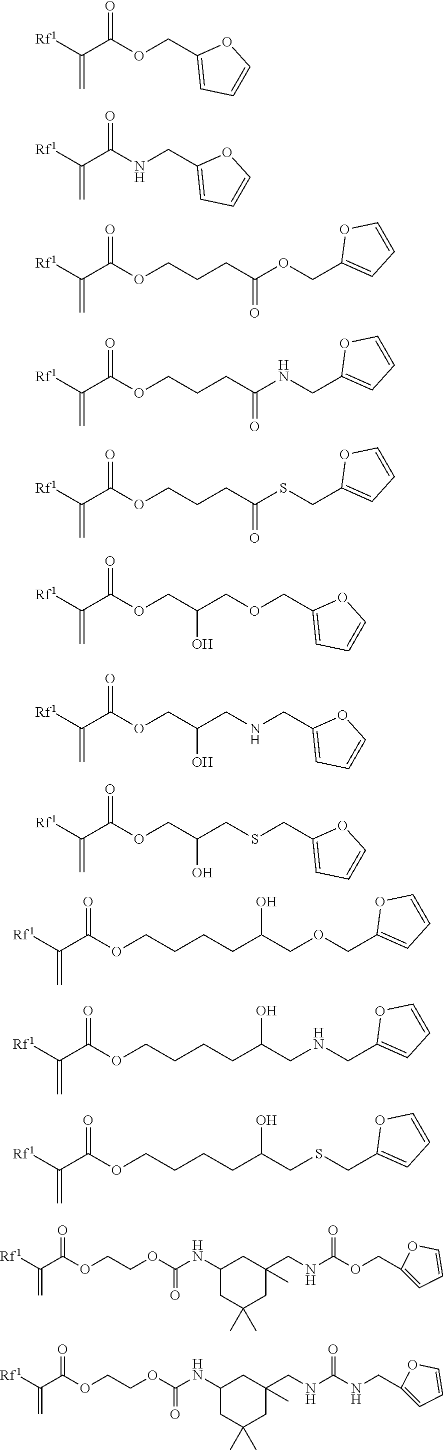

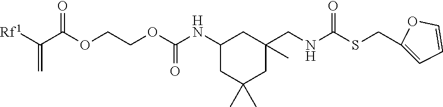

As the polymer-type furyl group-containing compound (hereinafter, also referred to as a furyl group-containing polymer), a resin including a repeating unit including a furyl group is preferable, and a resin including a repeating unit derived from the compound represented by Formula (fur-1) is more preferable. The concentration of the furyl group in the furyl group-containing polymer is preferably 0.5 to 6.0 mmol and still more preferably 1.0 to 4.0 mmol per 1 g of the furyl group-containing polymer. In a case where the concentration of the furyl group is 0.5 mmol or more, preferably 1.0 mmol or more, it is easy to form a pixel having excellent solvent resistance and the like. In a case where the concentration of the furyl group is 6.0 mmol or less, preferably 4.0 mmol or less, the temporal stability of the photosensitive resin composition is good.

The furyl group-containing polymer may include a repeating unit having an acid group and/or a repeating unit having a polymerizable group, in addition to the repeating unit having a furyl group. Examples of the acid group include a carboxyl group, a phosphoric acid group, a sulfo group, and a phenolic hydroxy group. Examples of the polymerizable group include ethylenically unsaturated bond-containing groups such as a vinyl group, a (meth)allyl group, and a (meth)acryloyl group. In a case where the furyl group-containing polymer includes a repeating unit having an acid group, the acid value thereof is preferably 10 to 200 mgKOH/g and more preferably 40 to 130 mgKOH/g.

In a case where the furyl group-containing polymer includes a repeating unit having a polymerizable group, it is easy to form a pixel having better solvent resistance and the like.

The furyl group-containing polymer can be produced by a method described in paragraph Nos. 0052 to 0101 of JP2017-194662A.

The content of the furyl group-containing compound in the total solid content of the photosensitive resin composition is preferably 0.1 to 70 mass %. The lower limit is preferably 2.5 mass % or more, more preferably 5.0 mass % or more, and still more preferably 7.5 mass % or more. The upper limit is preferably 65 mass % or less, more preferably 60 mass % or less, and still more preferably 50 mass % or less. In addition, in a case where the furyl group-containing polymer is used as the furyl group-containing compound, the content of the furyl group-containing polymer in the resin included in the photosensitive resin composition is preferably 0.1 to 100 mass %. The lower limit is preferably 10 parts by mass or more and more preferably 15 parts by mass or more. The upper limit is preferably 90 parts by mass or less, more preferably 80 parts by mass or less, and still more preferably 70 parts by mass or less. The furyl group-containing compound may be used singly or in combination of two or more kinds thereof. In a case of using two or more kinds thereof, the total content thereof is preferably within the above-described range.

<<Silane Coupling Agent>>

The photosensitive resin composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureide group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

The content of the silane coupling agent in the total solid content of the photosensitive resin composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, the total content thereof is preferably within the above-described range.

<<Curing Accelerator>>

The photosensitive resin composition according to the embodiment of the present invention can contain a curing accelerator. Examples of the curing accelerator include a polyfunctional thiol compound having two or more mercapto groups in a molecule. The polyfunctional thiol compound may also be added for the purpose of improving stability, odor, resolution, developability, adhesiveness, or the like. The polyfunctional thiol compound is preferably secondary alkanethiols and more preferably a compound represented by Formula (T1).

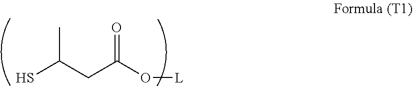

(in Formula (T1), n represents an integer of 2 to 4, and L represents a divalent to tetravalent linking group)

In Formula (T1), the linking group L is preferably an aliphatic group having 2 to 12 carbon atoms, and it is particularly preferable that n is 2 and L is an alkylene group having 2 to 12 carbon atoms.

Moreover, as the curing accelerator, a methylol-based compound (for example, the compounds exemplified as a crosslinking agent in paragraph No. 0246 of JP2015-034963A), amines, phosphonium salts, amidine salts, and amide compounds (each of which is the curing agent described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having an epoxy group, described in JP2011-253054A), onium salt compounds (for example, the compounds exemplified as an acid generator in paragraph No. 0216 of JP2015-034963A, and the compounds described in JP2009-180949A), or the like can also be used.

The content of the curing accelerator in the total solid content of the photosensitive resin composition is preferably 0.3 to 8.9 mass % and more preferably 0.8 to 6.4 mass %.

<<Polymerization Inhibitor>>

The photosensitive resin composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. The content of the polymerization inhibitor in the total solid content of the photosensitive resin composition is preferably 0.0001 to 5 mass %.

<<Surfactant>>

The photosensitive resin composition according to the embodiment of the present invention can contain a surfactant. As the surfactant, various surfactants such as a fluorine-based surfactant, a nonionic surfactant, a cationic surfactant, an anionic surfactant, or a silicon-based surfactant can be used. Examples of the surfactant include surfactants described in paragraph Nos. 0238 to 0245 of WO2015/166779A, the contents of which are incorporated herein by reference.

In the present invention, it is preferable that the surfactant is a fluorine-based surfactant. By containing a fluorine-based surfactant in the photosensitive resin composition, liquid characteristics (particularly, fluidity) are further improved, and liquid saving properties can be further improved. In addition, it is possible to form a cured film with a small thickness unevenness.

The fluorine content in the fluorine-based surfactant is preferably 3 to 40 mass %, more preferably 5 to 30 mass %, and particularly preferably 7 to 25 mass %. The fluorine-based surfactant in which the fluorine content is within the above-described range is effective in terms of the evenness of the thickness of the coating film or liquid saving properties and the solubility of the surfactant in the photosensitive resin composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used. Examples of such a fluorine-based surfactant include fluorine-based surfactants described in JP2016-216602A, the contents of which are incorporated herein by reference.

As the fluorine-based surfactant, a block polymer can also be used. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

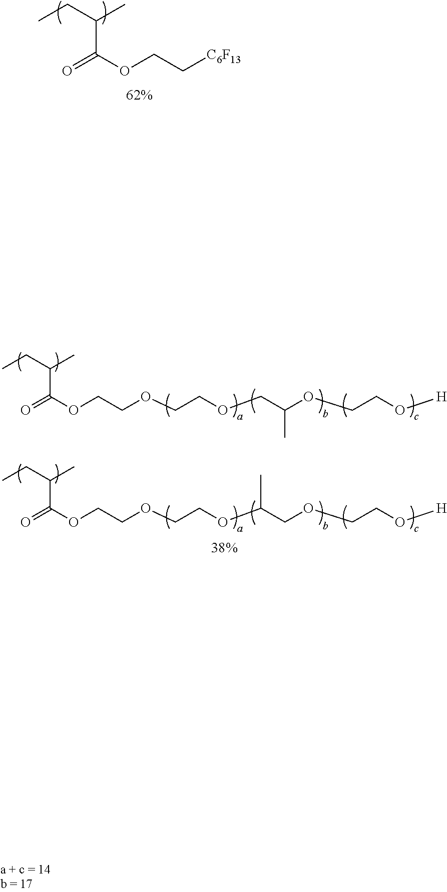

The weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

The content of the surfactant in the total solid content of the photosensitive resin composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

<<Antioxidant>>

The photosensitive resin composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used.

The content of the antioxidant in the total solid content of the photosensitive resin composition is preferably 0.01 to 20 mass % and more preferably 0.3 to 15 mass %. The antioxidant may be used singly or in combination of two or more kinds thereof. In a case where two or more kinds thereof are used, the total content thereof is preferably within the above-described range.

<<Other Components>>

Optionally, the photosensitive resin composition according to the embodiment of the present invention may further contain a sensitizer, a filler, a thermal curing accelerator, a plasticizer, and other auxiliary agents (for example, conductive particles, an anti-foaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph Nos. 0183 and later of JP2012-003225A (corresponding to paragraph No. 0237 of US2013/0034812A) and paragraph Nos. 0101 to 0104 and 0107 to 0109 of JP2008-250074A, the content of which is incorporated herein by reference. In addition, optionally, the photosensitive resin composition according to the embodiment of the present invention may contain a potential antioxidant. Examples of the potential antioxidant include a compound in which a portion that functions as the antioxidant is protected by a protective group and the protective group is desorbed by heating the compound at 100° C. to 250° C. or by heating the compound at 80° C. to 200° C. in the presence of an acid/a base catalyst. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of the cured film to be obtained, the photosensitive resin composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The photosensitive resin composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to “0052 of JP2017-129774A, the compounds described in paragraph Nos. 0031 to 0034, 0058, and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

In the photosensitive resin composition according to the embodiment of the present invention, the content of liberated metal which is not bonded to or coordinated with a pigment or the like is preferably 100 ppm or less, more preferably 50 ppm or less, and still more preferably 10 ppm or less, it is particularly preferable to not contain the liberated metal substantially. According to this aspect, effects such as stabilization of pigment dispersibility (restraint of aggregation), improvement of spectral characteristics due to improved dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberated metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the photosensitive resin composition according to the embodiment of the present invention, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F, Cl, Br, I, and anions thereof. Examples of a method for reducing liberated metals and halogens in the photosensitive resin composition include washing with ion exchange water, filtration, ultrafiltration, and purification with an ion exchange resin.

It is also preferable that the photosensitive resin composition according to the embodiment of the present invention does not substantially include terephthalic acid ester. Here, the “does not substantially include” means that the content of terephthalic acid ester is 1000 mass ppb or less in the total amount of the photosensitive resin composition, and it is more preferable to be 100 mass ppb or less and particularly preferable to be 0.

The moisture content in the photosensitive resin composition according to the embodiment of the present invention is usually 3 mass % or less, preferably 0.01 to 1.5 mass % and more preferably in a range of 0.1 to 1.0 mass %. The moisture content can be measured by a Karl Fischer method.

The photosensitive resin composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa×s to 50 mPa×s, and more preferably 0.5 mPa×s to 20 mPa×s at 25° C. As for a method for measuring the viscosity, the viscosity can be measured, for example, with a temperature being adjusted to 25° C., using a viscometer RE85L (rotor: 1° 34′×R24, measurement range of 0.6 to 1,200 mPa×s) manufactured by Toki Sangyo Co., Ltd.

In a case where the photosensitive resin composition according to the embodiment of the present invention is used as a color filter in applications for a liquid crystal display device, the voltage holding ratio of a liquid crystal display element comprising a color filter is preferably 70% or more, and more preferably 90% or more. A known method for obtaining a high voltage holding ratio can be appropriately incorporated, and examples of typical methods include use of high-purity materials (for example, reduction in ionic impurities) and control of the amount of acidic functional groups in a composition. The voltage holding ratio can be measured by, for example, the methods described in paragraph 0243 of JP2011-008004A and paragraphs 0123 to 0129 of JP2012-224847A.

<Storage Container>

A storage container of the photosensitive resin composition according to the embodiment of the present invention is not particularly limited, and a known storage container can be used. In addition, as the storage container, in order to suppress infiltration of impurities into the raw materials or the photosensitive resin composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-123351A. In addition, for the purpose of preventing metal elution from the container inner wall, improving storage stability of the photosensitive resin composition, and suppressing the alteration of components, it is also preferable that the container inner wall is formed of glass, stainless steel, or the like.

<Method for Preparing Photosensitive Resin Composition>

The photosensitive resin composition according to the embodiment of the present invention can be prepared by mixing the above-described components with each other. During the preparation of the photosensitive resin composition, all the components may be dissolved and/or dispersed in a solvent at the same time to prepare the photosensitive resin composition. Optionally, two or more solutions or dispersion liquids in which the respective components are appropriately blended may be prepared, and the solutions or dispersion liquids may be mixed with each other during use (during application) to prepare the photosensitive resin composition.

In addition, in the preparation of the photosensitive resin composition, a process of dispersing the pigment is preferably included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. A material, a device, process conditions, and the like used in the salt milling step can be found in, for example, JP2015-194521A and JP2012-046629A.

During the preparation of the photosensitive resin composition, it is preferable that the photosensitive resin composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Advantec Toyo Kaisha., Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and then the filtering using the second filter may be performed on a mixture of the dispersion liquid and other components.

<Cured Film>

The cured film according to an embodiment of the present invention is a cured film formed from the above-described photosensitive resin composition according to the embodiment of the present invention. The cured film according to the embodiment of the present invention can be preferably used as a colored pixel of a color filter. As the colored pixel, a cyan pixel is preferable. The thickness of the cured film according to the embodiment of the present invention can be appropriately adjusted according to the purpose. For example, the thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

In the cured film according to the embodiment of the present invention, the average transmittance of light in a wavelength range of 400 to 530 nm in a thickness direction of the film is preferably 70% or more, more preferably 80% or more, and still more preferably 85% or more. In addition, the minimum value of the transmittance of light in the wavelength range of 400 to 530 nm in the thickness direction of the film is preferably 40% or more, more preferably 50% or more, and still more preferably 60% or more. In addition, the average transmittance of light in a wavelength range of 610 to 700 nm in the thickness direction of the film is preferably 30% or less, more preferably 25% or less, and still more preferably 20% or less. In addition, the maximum value of the transmittance of light in the wavelength range of 610 to 700 nm in the thickness direction of the film is preferably 40% or less, more preferably 30% or less, and still more preferably 25% or less.

In the cured film according to the embodiment of the present invention, it is preferable that the peak value of the transmittance exists in a wavelength range of 400 to 530 nm in the transmission spectrum of light in a wavelength range of 400 to 700 nm in the thickness direction of the film. In addition, it is preferable that a wavelength having a transmittance of 50% of the peak value (hereinafter, this wavelength is also referred to as λ^{T50}) exists in a wavelength range of 540 to 600 nm. In addition, it is preferable that a wavelength having a transmittance of 20% of the peak value (hereinafter, this wavelength is also referred to as λ^{T20}) exists in a wavelength range of 560 to 620 nm. λ^{T50} preferably exists in a wavelength range of 545 to 595 nm, and more preferably exists in a wavelength range of 550 to 590 nm. λ^{T20} preferably exists in a wavelength range of 565 to 615 nm, and more preferably exists in a wavelength range of 560 to 610 nm. In addition, the difference between λ^{T20} and λ^{T50} (λ^{T20}−λ^{T50}) is preferably 5 to 80 nm, more preferably 7 to 50 nm, and still more preferably 10 to 30 nm.

<Color Filter>

Next, the color filter according to the embodiment of the present invention will be described. The color filter according to the embodiment of the present invention includes the above-described cured film according to the embodiment of the present invention. More preferably, the color filter according to the embodiment of the present invention has the cured film according to the embodiment of the present invention as a pixel of the color filter. Still more preferably, the color filter according to the embodiment of the present invention has the cured film according to the embodiment of the present invention as a cyan pixel of the color filter. The color filter according to the embodiment of the present invention can be used for a solid-state imaging element such as a charge coupled device (CCD) and a complementary metal-oxide semiconductor (CMOS), an image display device, or the like.

In the color filter according to the embodiment of the present invention, the thickness of the cured film according to the embodiment of the present invention can be appropriately adjusted depending on the purposes. The thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

In the color filter according to the embodiment of the present invention, the width of the pixel is preferably 0.5 to 20.0 μm. The lower limit is preferably 1.0 μm or more and more preferably 2.0 μm or more. The upper limit is preferably 15.0 μm or less and more preferably 10.0 μm or less. In addition, the Young's modulus of the pixel is preferably 0.5 to 20 GPa and more preferably 2.5 to 15 GPa.

Each pixel included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω×cm or more and more preferably 10¹¹ Ω×cm or more. The upper limit is not specified, but is, for example, preferably 10¹⁴ Ω×cm or less. The volume resistivity value of the pixel can be measured, for example, using an ultrahigh resistance meter 5410 (manufactured by Advantest Corporation).

In addition, in the color filter according to the embodiment of the present invention, a protective layer may be provided on the surface of the cured film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and still more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an inkjet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of a specific wavelength (for example, ultraviolet rays, near-infrared rays, and the like), a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. Examples of the ultraviolet absorber and near-infrared absorber include the above-described materials. The content of these additives can be appropriately adjusted, but is preferably 0.1 to 70 mass % and still more preferably 1 to 60 mass % with respect to the total weight of the protective layer.

In addition, as the protective layer, the protective layers described in paragraph Nos. 0073 to 0092 of JP2017-151176A can also be used.

<Method for Manufacturing Color Filter>

Next, a method for manufacturing the color filter will be described. The color filter according to the embodiment of the present invention can be manufactured through a step of forming a photosensitive resin composition layer on a support using the above-described photosensitive resin composition according to the embodiment of the present invention, and a step of forming a pattern on the photosensitive resin composition by a photolithography method.

Pattern formation by the photolithography method preferably includes a step of forming a photosensitive resin composition layer on a support using the photosensitive resin composition according to the embodiment of the present invention, a step of exposing the photosensitive resin composition layer in a patterned manner, and a step of removing a non-exposed portion of the photosensitive resin composition layer by development to form a pattern (pixel). A step (pre-baking step) of baking the photosensitive resin composition layer and a step (post-baking step) of baking the developed pattern (pixel) may be provided, optionally.

In the step of forming a photosensitive resin composition layer, the photosensitive resin composition layer is formed on a support using the photosensitive resin composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of substances, or planarize the surface of the substrate.

As a method of applying the photosensitive resin composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. The application method using an ink jet method is not particularly limited, and examples thereof include a method (in particular, pp. 115 to 133) described in “Extension of Use of Ink Jet —Infinite Possibilities in Patent-” (published on February, 2005, S.B. Research Co., Ltd.) and methods described in JP2003-262716A, JP2003-185831A, JP2003-261827A, JP2012-126830A, and JP2006-169325A. In addition, as the method of applying the photosensitive resin composition, methods described in WO2017/030174A and WO2017/018419A can also be used, the contents of which are incorporated herein by reference.

The photosensitive resin composition layer formed on the support may be dried (pre-baked). In a case of producing a cured film by a low-temperature process, pre-baking may not be performed. In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. The pre-baking time is preferably 10 to 300 seconds, more preferably 40 to 250 seconds, and still more preferably 80 to 220 seconds. Pre-baking can be performed using a hot plate, an oven, or the like.

Next, the photosensitive resin composition layer is exposed in a patterned manner (exposing step). For example, the photosensitive resin composition layer can be exposed in a patterned manner using a stepper exposure device or a scanner exposure device through a mask having a predetermined mask pattern. As a result, an exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the photosensitive resin composition layer is removed by development to form a pattern (pixel). The non-exposed portion of the photosensitive resin composition layer can be removed by development using a developer. Thus, the photosensitive resin composition layer of the non-exposed portion in the exposing step is eluted into the developer, and as a result, only a photocured portion remains. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

Examples of the developer include an organic solvent and an alkali developer, and an alkali developer is preferably used. As the alkali developer, an alkaline solution (alkali developer) in which an alkaline agent is diluted with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium hydrogen carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the photosensitive resin composition layer after development while rotating the support on which the photosensitive resin composition layer after development has been formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to perform an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

<Solid-State Imaging Element>

A solid-state imaging element according to an embodiment of the present invention has the above-described cured film according to the embodiment of the present invention. Examples of a preferred aspect of the solid-state imaging element include an aspect in which the cured film is a cyan pixel, and the solid-state imaging element further includes a yellow pixel and a magenta pixel.

The configuration of the solid-state imaging element according to the embodiment of the present invention is not particularly limited as long as the solid-state imaging element is configured to include the cured film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device-protective film formed of silicon nitride or the like, which is formed to cover the entire surface of the light-shielding film and the light receiving portion of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice form by a partition wall. In this case, it is preferable that the partition wall has a lower refractive index than each colored pixel. Examples of an imaging device having such a structure include the devices described in JP2012-227478A, JP2014-179577A, WO2018/043654A, and US2018/0040656A. An imaging device including the solid-state imaging element according to the embodiment of the present invention can also be used as a vehicle-mounted camera or a monitoring camera, in addition to a digital camera or electronic equipment (mobile phones or the like) having an imaging function.

<Image Display Device>

The image display device according to the embodiment of the present invention has the cured film according to the embodiment of the present invention. Examples of the image display device include a liquid crystal display device or an organic electroluminescent display device. The definitions of image display devices or the details of the respective image display devices are described in, for example, “Electronic Display Device (edited by Akio Sasaki, Kogyo Chosakai Publishing Co., Ltd., published in 1990)”, “Display Device (edited by Sumiaki Ibuki, Sangyo Tosho Co., Ltd., published in 1989)”, and the like. In addition, the details of a liquid crystal display device can be found in, for example, “Next-Generation Liquid Crystal Display Techniques (edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Measurement of Weight-Average Molecular Weight (Mw)>

The weight-average molecular weight (Mw) of a resin was measured by gel permeation chromatography (GPC) according to the following conditions.

Types of columns: columns formed by connection of TOSOH TSKgel Super HZM-H, TOSOH TSKgel Super HZ4000, and TOSOH TSKgel Super HZ2000

Developing solvent: tetrahydrofuran

Column temperature: 40° C.

Flow rate (amount of a sample to be injected): 1.0 μL (sample concentration: 0.1 mass %)

Device name: HLC-8220GPC manufactured by Tosoh Corporation

Detector: refractive index (RI) detector

Calibration curve base resin: polystyrene resin

<Method of Measuring Acid Value>

A measurement sample was dissolved in a mixed solution of tetrahydrofuran/water=9/1 (mass ratio), and the obtained solution was subjected to neutralization titration with a 0.1 mol/L sodium hydroxide aqueous solution at 25° C. using a potentiometric titrator (trade name: AT-510, manufactured by KYOTO ELECTRONICS MANUFACTURING CO., LTD.). An inflection point of a titration pH curve was set as a titration end point, and the acid value was calculated from the following equation.

A=56.11×Vs×0.1×f/w

A: acid value (mgKOH/g)

Vs: amount (mL) of the 0.1 mol/L sodium hydroxide aqueous solution used for the titration

f: titer of the 0.1 mol/L sodium hydroxide aqueous solution

w: mass (g) of the measurement sample (expressed in terms of solid contents)

<Measuring Method of Amine Value>

A measurement sample was dissolved in acetic acid, and the obtained solution was subjected to neutralization titration with a 0.1 mol/L perchloric acid/acetic acid solution at 25° C. using a potentiometric titrator (trade name: AT-510, manufactured by KYOTO ELECTRONICS MANUFACTURING CO., LTD.). An inflection point of a titration pH curve was set as a titration end point, and the amine value was calculated from the following equation.

B=56.11×Vs×0.1×f/w

B: amine value (mgKOH/g)

Vs: amount (mL) of the 0.1 mol/L perchloric acid/acetic acid solution used for the titration

f: titer of the 0.1 mol/L perchloric acid/acetic acid solution

w: mass (g) of the measurement sample (expressed in terms of solid contents)

<Measuring Method of Average Secondary Particle Diameter of Pigment>

The average secondary particle diameter of the pigment was measured by directly measuring the size of the secondary particle of the pigment from an electron micrograph using a transmission electron microscope (TEM). Specifically, the minor axis diameter and the major axis diameter of the secondary particle of each pigment were measured, and the average thereof was defined as the particle diameter of the pigment. Next, for each of the 100 pigments, the volume of each pigment was obtained by approximating it to a cube having the obtained particle diameter, and the volume average particle diameter was defined as the average secondary particle diameter.

<Preparation of Photosensitive Resin Composition>

Colorants of the types described in the following tables, dispersants of the types described in the following tables, and a part of solvents described in the following tables were mixed, and 230 parts by mass of zirconia beads having a diameter of 0.3 mm were added thereto to perform a dispersion treatment for 5 hours using a paint shaker. The beads were separated by filtration, and a pigment dispersion liquid having a solid content of 20 weight % was produced.

Next, the obtained pigment dispersion liquid, the rest of the solvents of the types described in the following tables, post-added resins of the types described in the following tables, polymerizable compounds of the types described in the following tables, photopolymerization initiators of the types described in the following tables, and ultraviolet absorbers of the types described in the following tables were mixed to prepare a photosensitive resin composition. The following tables show the blending amount of each component in the photosensitive resin composition. The numerical value of each component indicates parts by mass. In addition, the total content (mass %) of C. I. Pigment Blue 15:3 (PB 15:3) and C. I. Pigment Blue 15:4 (PB 15:4) in the colorant, the content (mass %) of the ultraviolet absorber in the total solid content of the photosensitive composition, the content (parts by mass) of the ultraviolet absorber with respect to 100 parts by mass of the photopolymerization initiator, and the content (parts by mass) of the ultraviolet absorber with respect to 100 parts by mass of the polymerizable compound are shown. Yellow composition and Magenta composition shown in the table are photosensitive resin compositions for color mixing evaluation, which will be described later.

TABLE 1

| | | | | | | | | | | Comparative | Comparative | Comparative | Comparative | Comparative |
|---|---|---|---|---|---|---|---|---|---|---|---|---|---|---|
| | Type | Example 1 | Example 2 | Example 3 | Example 4 | Example 5 | Example 6 | Example 7 | Example 8 | example 1 | example 2 | example 3 | example 4 | example 5 |
| Colorant | PB15:3 | 2.1 | | 0.5 | 1.1 | 2.1 | 2.1 | | | 0.5 | 0.5 | | | |
| | PB15:4 | | 2.2 | 0.5 | 1.0 | | | 3.1 | 1.4 | 0.5 | 0.5 | | | |
| | PcAl | | | | | | | | | | | | 2.3 | 2.3 |
| | PY150 | | | | | 0.1 | | | | | | | | |
| | PG7 | | | 0.8 | | | | | | 0.9 | 0.9 | 0.9 | | |
| Dispersant | P1 | 2.3 | | 2.3 | | 2.3 | 2.3 | | | | | | | |
| | P2 | | 2.3 | | | | | | | 2.4 | 2.4 | 2.3 | 1.9 | |
| | P3 | 1.2 | 1.2 | 1.2 | 3.5 | 1.2 | 1.2 | 0.2 | 0.1 | 1.4 | 0.7 | | 1.4 | 3.3 |
| | P4 | | | | | | | 1.4 | 0.4 | | | | | |
| Post-added resin | P3 | 1.1 | 0.9 | 1.5 | 1.2 | 1.0 | 1.1 | 1.8 | 4.6 | 1.2 | 0.6 | 0.6 | 1.2 | 1.2 |
| Polymerizable compound | M1 | | | | | | 1.1 | 1.2 | 1.2 | | | | | |
| | M2 | 2.7 | 2.7 | 2.7 | 2.7 | 2.7 | 1.6 | | | 2.6 | 2.6 | 2.6 | 2.5 | |
| | M3 | | | | | | | 2.9 | 2.9 | | | | | |
| Photopolymerization | I1 | | | | 0.1 | | | | | | | | | |
| initiator | I2 | 0.5 | 0.5 | 0.5 | 0.4 | 0.5 | 0.5 | 1.6 | 1.6 | 0.5 | 0.5 | 0.5 | 0.5 | 0.5 |
| Ultraviolet absorber | U1 | 0.10 | 0.20 | | | 0.10 | 0.10 | 0.86 | 0.86 | 0.01 | 1.30 | 0.20 | 0.20 | 0.20 |
| | U2 | | | 0.20 | | | | | | | | | | |
| | U3 | | | | 0.50 | | | | | | | | | |
| Surfactant | W1 | 0.01 | 0.01 | 0.01 | 0.01 | 0.01 | 0.01 | 0.01 | 0.01 | 0.01 | 0.01 | 0.01 | 0.01 | 0.01 |
| Additive | X1 | | | | | | | 0.4 | 0.4 | | | | | |
| Solvent | S1 | 90.0 | 90.0 | 89.8 | 85.0 | 90.0 | 90.0 | 85.3 | 85.3 | 90.0 | 90.0 | 92.9 | 90.0 | 90.0 |
| | S2 | | | | 4.5 | | | 1.2 | 1.2 | | | | | |

| | | | | | | | | | | | | | |
|---|---|---|---|---|---|---|---|---|---|---|---|---|---|
| Total content (mass %) of C. I. Pigment Blue | 100.0 | 100.0 | 55.6 | 100.0 | 95.5 | 100.0 | 100.0 | 100.0 | 52.6 | 52.6 | 0.0 | 0.0 | 0.0 |
| 15:3 (PB 15:3) and C. I. Pigment Blue 15:4 | | | | | | | | | | | | | |
| (PB 15:4) in colorant | | | | | | | | | | | | | |
| Content (mass %) of ultraviolet absorber in | 1.0 | 2.0 | 2.0 | 4.8 | 1.0 | 1.0 | 6.4 | 6.4 | 0.0 | 13.0 | 2.8 | 2.0 | 2.0 |
| total solid content of photosensitive | | | | | | | | | | | | | |
| composition | | | | | | | | | | | | | |
| Content (parts by mass) of ultraviolet absorber | 20.0 | 40.0 | 40.0 | 100.0 | 20.0 | 20.0 | 53.8 | 53.8 | 1.0 | 260.0 | 40.0 | 40.0 | 40.0 |
| with respect to 100 parts by mass of | | | | | | | | | | | | | |
| photopolymerization initiator | | | | | | | | | | | | | |
| Content (parts by mass) of ultraviolet absorber | 3.7 | 7.4 | 7.4 | 18.5 | 3.7 | 3.7 | 21.0 | 21.0 | 0.2 | 50.0 | 7.7 | 8.0 | 8.0 |
| with respect to 100 parts by mass of | | | | | | | | | | | | | |
| polymerizable compound | | | | | | | | | | | | | |

TABLE 2

| | | Yellow | Magenta |
|---|---|---|---|
| | Type | composition | composition |
| Colorant | PY150 | 4.8 | |
| | PR122 | | 6.1 |
| Dispersant | P3 | 1.2 | 0.4 |
| | P4 | | 2.6 |
| | P5 | 2.9 | |
| Post-added resin | P3 | 2.4 | |
| | P6 | | 2.3 |
| Polymerizable compound | M3 | 2.3 | |
| | M4 | | 2.6 |
| Photopolymerization initiator | I2 | 0.6 | 0.4 |
| Ultraviolet absorber | U1 | 0.70 | 0.37 |
| Surfactant | W1 | 0.04 | 0.04 |
| Additive | X2 | | 0.12 |
| Solvent | S1 | 85.1 | 83.2 |
| | S2 | | 1.9 |

The raw materials described by abbreviations shown in the above table are as follows.

### (Colorant)

PB 15:3: C. I. Pigment Blue 15:3 (average secondary particle diameter: 68 nm)

PB 15:4: C. I. Pigment Blue 15:4 (average secondary particle diameter: 71 nm)

PcAl: compound having the following structure (aluminum phthalocyanine, average secondary particle diameter: 94 nm)

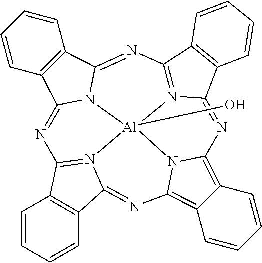

PY 150: C. I. Pigment Yellow 150 (average secondary particle diameter: 81 nm)

PG 7: C. I. Pigment Green 7 (average secondary particle diameter: 80 nm)

PR 122: C. I. Pigment Red 122 (average secondary particle diameter: 67 nm)

(Dispersant and Post-Added Resin)

P1: DISPERBYK-2001 (manufactured by BYK Chemie Japan, acid value: 19 mgKOH/g, amine value: 29 mgKOH/g, acrylic resin)

P2: Efka PX 4300 (manufactured by BASF, amine value: 57 mgKOH/g, acrylic resin)

P3: resin having the following structure (weight-average molecular weight=10000, acid value: 31.5 mgKOH/g, amine value: 0 mgKOH/g, numerical value added to a main chain represents a molar ratio of a repeating unit)

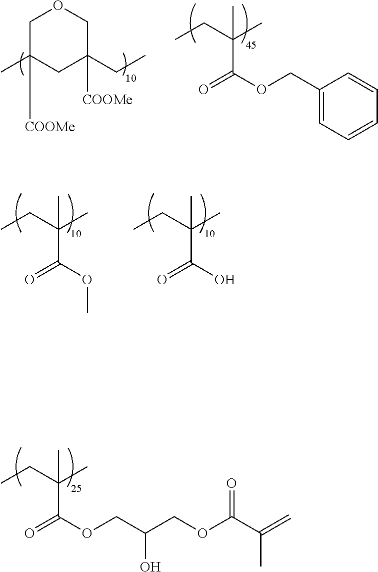

P4: resin having the following structure (weight-average molecular weight=24000, acid value: 52.5 mgKOH/g, amine value: 0 mgKOH/g, numerical value added to a main chain represents a molar ratio of a repeating unit and numerical value added to a side chain represents the number of repeating units)

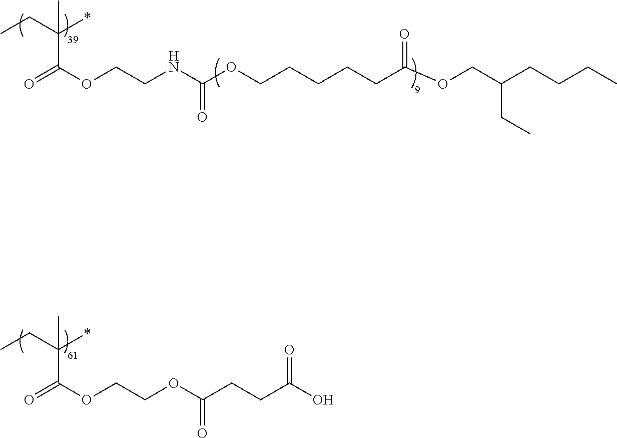

P5: resin having the following structure (weight-average molecular weight=21000, acid value: 36.0 mgKOH/g, amine value: 47 mgKOH/g; x=48, y=12, a/b/c/d/e=36/4/35/1/24 (molar ratio))

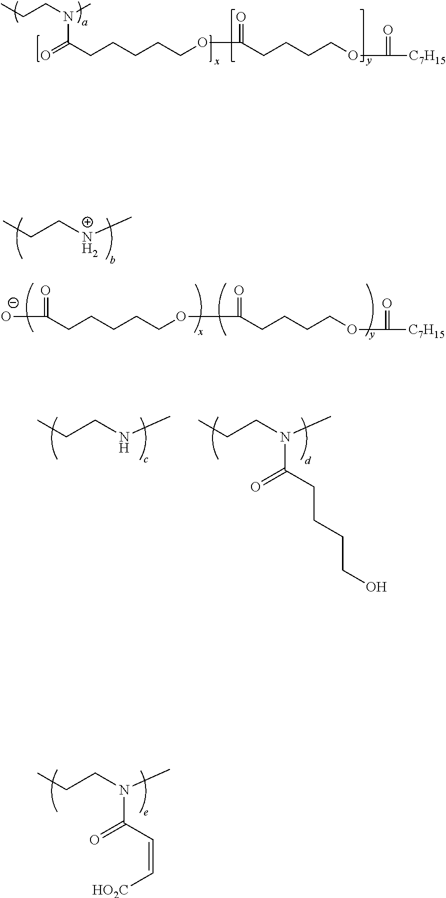

P6: resin having the following structure (weight-average molecular weight=12000, acid value: 195.4 mgKOH/g, amine value: 0 mgKOH/g, numerical value added to a main chain represents a molar ratio of a repeating unit)

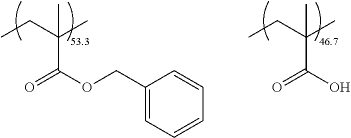

(Polymerizable Compound)

M1: compound having the following structure

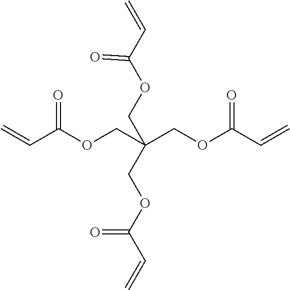 [SMILES: C=CC(=O)OCC(COC(=O)C=C)(COC(=O)C=C)COC(=O)C=C]

M2: mixture of a compound having the following structure (compound on the left: compound on the right=7:3 (mass ratio))

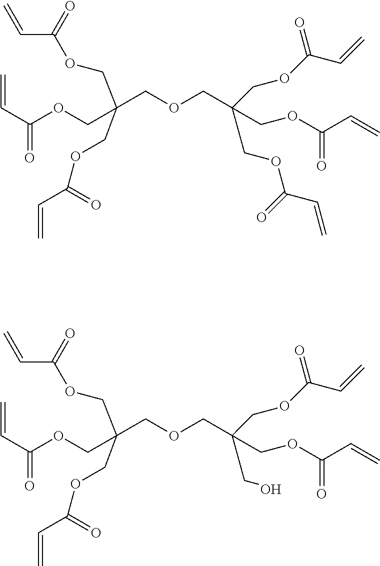 [SMILES: C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

M3: compound having the following structure (l+m+n+o+p+q=12)

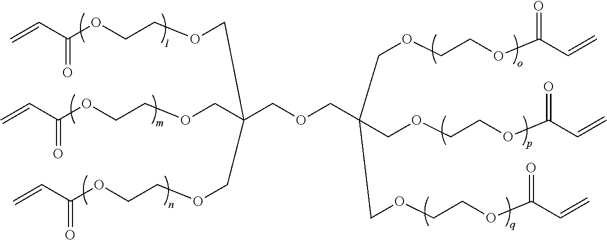

M4: compound having the following structure

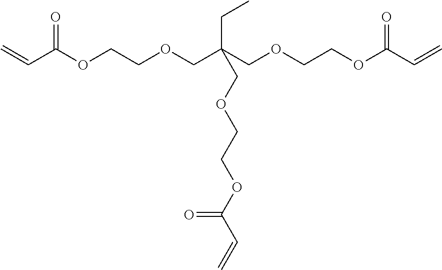 [SMILES: C=CC(=O)OCCOCC(CC)(COCCOC(=O)C=C)COCCOC(=O)C=C]

(Photopolymerization Initiator)

I1: compound having the following structure (α-aminoketone compound)

I2: compound having the following structure (oxime compound)

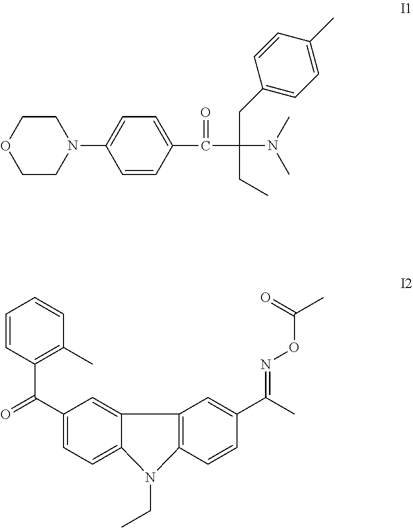 [SMILES: CCC(Cc1ccc(C)cc1)(C(=O)c1ccc(N2CCOCC2)cc1)N(C)C ; CCn1c2ccc(C(=O)c3ccccc3C)cc2c2cc(/C(C)=N/OC(C)=O)ccc21]

(Ultraviolet Absorber)

U1: compound having the following structure (conjugated diene compound)

U2: compound having the following structure (triazine compound)

U3: compound having the following structure (benzotriazole compound)

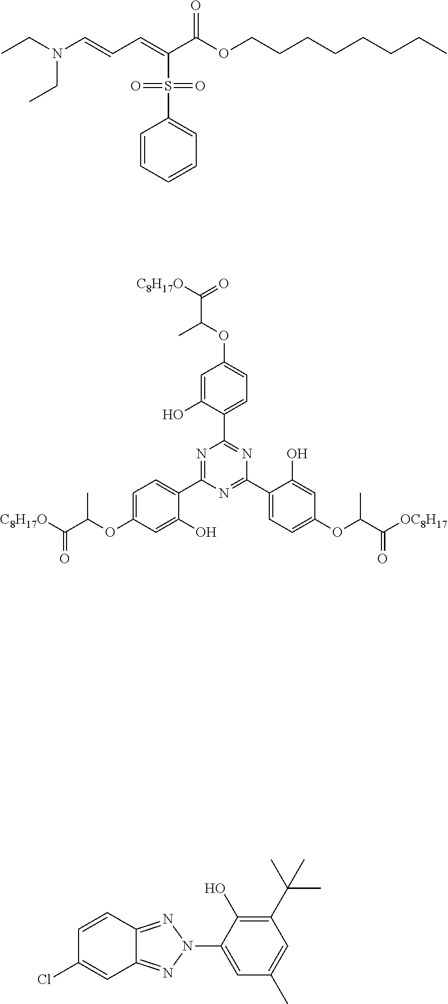

(Surfactant)

W1: compound having the following structure (fluorine-based surfactant, weight-average molecular weight=14000; “%” representing the proportion of a repeating unit is mol %)

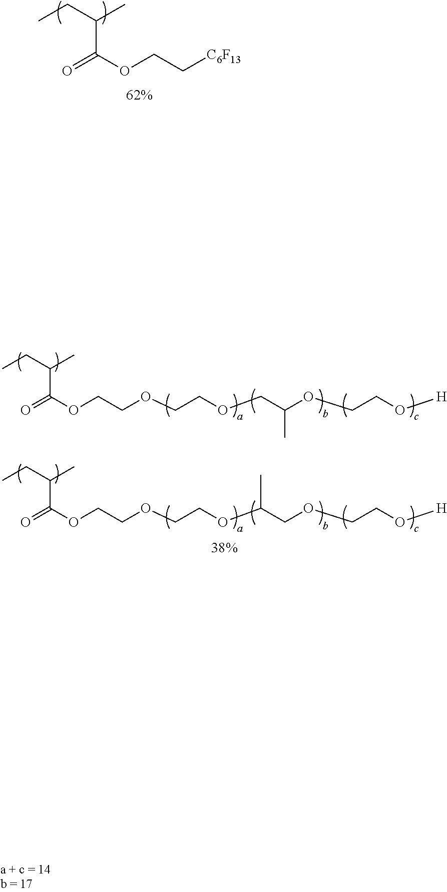

(Other Additives)

X1: 1,2-epoxy-4-(2-oxiranyl)cyclohexane adduct of 2,2-bis(hydroxymethyl)-1-butanol (compound having the following structure, epoxy compound)

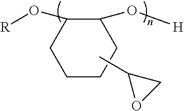

X2: compound having the following structure (silane coupling agent)

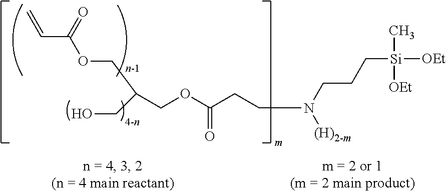

(Solvent)

S1: propylene glycol monomethyl ether acetate

S2: propylene glycol monomethyl ether

### EVALUATION

(Evaluation of Spectral Characteristics as Cyan Color)

The photosensitive resin composition was applied to a glass substrate according to a spin coating method, subjected to a heating treatment (pre-baking) for 120 seconds using a hot plate at 100° C., exposed with i-rays at an exposure amount of 1000 mJ/cm², and then heated at 200° C. for 5 minutes to produce a cured film having a thickness of 0.6 μm. Light transmittance (transmittance) of the obtained cured film in a range of 400 to 700 nm was measured by using MCPD-3000 manufactured by OTSUKA ELECTRONICS Co., LTD. In a case where the average value of the transmittance at 400 to 530 nm was defined as T1, the average value of the transmittance at 610 to 700 nm was defined as T2, and 50% transmittance was defined as λ50, spectral characteristics as cyan color were determined based on the following standard. A case where all three items are satisfied is defined as A, a case where only two items are satisfied is defined as B, a case where only one item is satisfied is defined as C, and a case where none of these is satisfied is defined as D.
T1 was 70% or more.
T2 was 30% or less.
λ50 was within a range of 540 to 590 nm.

(Evaluation of Light Resistance)

The photosensitive resin composition was applied to a glass substrate according to a spin coating method, subjected to a heating treatment (pre-baking) for 120 seconds using a hot plate at 100° C., exposed with i-rays at an exposure amount of 1000 mJ/cm², and then heated at 200° C. for 5 minutes to produce a cured film having a thickness of 0.6 μm. Light transmittance (transmittance) of the obtained cured film in a wavelength range of 400 to 700 nm was measured by using MCPD-3000 manufactured by OTSUKA ELECTRONICS Co., LTD. Next, the cured film produced above was irradiated with light of 100000 Lux over 1000 hours (total irradiation amount: 100 million Lux·hr) using a light resistance tester (Super Xenon Weather Meter SX75, manufactured by Suga Test Instruments Co., Ltd.). The transmittance of the cured film after light irradiation was measured, and light resistance was evaluated based on the following standard.

A: integrated value of the transmittance of the cured film after light irradiation at a wavelength of 400 to 700 nm was 97% or more of the integrated value of the transmittance of the cured film before light irradiation at a wavelength of 400 to 700 nm.

B: integrated value of the transmittance of the cured film after light irradiation at a wavelength of 400 to 700 nm was 95% or more and less than 97% of the integrated value of the transmittance of the cured film before light irradiation at a wavelength of 400 to 700 nm.

C: integrated value of the transmittance of the cured film after light irradiation at a wavelength of 400 to 700 nm was less than 95% of the integrated value of the transmittance of the cured film before light irradiation at a wavelength of 400 to 700 nm.

(Evaluation of Rectangularity)

A silicon wafer having a diameter of 8 inches (1 inch=25.4 mm) was heat-treated in an oven at 200° C. for 30 minutes. Next, an undercoat resist solution (CT-4000, manufactured by Fujifilm Electronic Materials Co., Ltd.) was applied to this silicon wafer so that the film thickness after drying was 0.1 μm, and heated and dried in an oven at 220° C. for 1 hour to form an undercoat layer, thereby obtaining a silicon wafer substrate with an undercoat layer.

The photosensitive resin composition was applied onto the undercoat layer of the silicon wafer substrate with an undercoat layer produced above. Next, a heating treatment (pre-baking) was performed for 120 seconds using a hot plate at 100° C. Next, using an i-ray stepper exposure device FPA-3000 i5+(manufactured by Canon Inc.), the silicon wafer was exposed at a wavelength of 365 nm through a mask having a pattern at an exposure amount of 500 mJ/cm². As the mask, a mask having an island pattern of 1.4 μm×1.4 μm was used.

Next, the substrate on which the irradiated coating film was formed was placed on a horizontal rotary table of a spin-shower developing machine (DW-30 Type, manufactured by Chemitronics Co., Ltd.), and subjected to a puddle development at room temperature for 60 seconds using an alkali developer (CD-2060, manufactured by Fujifilm Electronic Materials Co., Ltd.). Next, the substrate after the puddle development was fixed on the horizontal rotary table by a vacuum chuck method, a rinse treatment (23 seconds×2 times) was performed by supplying pure water from above a rotation center in shower-like from an ejection nozzle while rotating the silicon wafer at a rotation speed of 50 rpm by a rotating device, and then the silicon wafer was spin-dried to form a pattern (pixel). Next, a heating treatment (post-baking) was performed for 300 seconds using a hot plate at 200° C. to form a pattern (pixel) of the cured film.

The pattern of the obtained cured film was cut, the cross section of the pattern of the cured film was observed by using a scanning electron microscope (SEM) at a magnification of 20000 times, and rectangularity was evaluated based on the following standard.

A: width of a surface of the pattern of the cured film on the substrate side (side in contact with the substrate) was 90% or more and 130% or less of the width of a surface on the opposite side of the substrate.

B: width of a surface of the pattern of the cured film on the substrate side (side in contact with the substrate) was 80% or more and less than 90% of the width of a surface on the opposite side of the substrate, or more than 130% and less than 160% thereof.

C: width of a surface of the pattern of the cured film on the substrate side (side in contact with the substrate) was less than 80% of the width of a surface on the opposite side of the substrate, or 160% or more thereof. Alternatively, the coating film was peeled off by development, and the pattern of the cured film could not be formed.

(Evaluation of Defects)

A silicon wafer having a diameter of 8 inches (1 inch=25.4 mm) was heat-treated in an oven at 200° C. for 30 minutes. Next, an undercoat resist solution (CT-4000, manufactured by Fujifilm Electronic Materials Co., Ltd.) was applied to this silicon wafer so that the film thickness after drying was 0.1 μm, and heated and dried in an oven at 220° C. for 1 hour to form an undercoat layer, thereby obtaining a silicon wafer substrate with an undercoat layer.

The photosensitive resin composition was applied onto the undercoat layer of the silicon wafer substrate with an undercoat layer produced above. Next, a heating treatment (pre-baking) was performed for 120 seconds using a hot plate at 100° C. Next, using an i-ray stepper exposure device FPA-3000 i5+(manufactured by Canon Inc.), the silicon wafer was exposed at a wavelength of 365 nm through a mask having a pattern at an exposure amount of 500 mJ/cm². As the mask, a mask capable of forming an island pattern of 1.4 μm×1.4 μm with a period of 2.8 μm×2.8 μm was used, and a shot having a size of 11 mm×11 mm was exposed to the entire region except the outer circumference of the wafer of 3 mm.

Next, the substrate on which the irradiated coating film was formed was placed on a horizontal rotary table of a spin-shower developing machine (DW-30 Type, manufactured by Chemitronics Co., Ltd.), and subjected to a puddle development at room temperature for 60 seconds using an alkali developer (CD-2060, manufactured by Fujifilm Electronic Materials Co., Ltd.). Next, the substrate after the puddle development was fixed on the horizontal rotary table by a vacuum chuck method, a rinse treatment (23 seconds×2 times) was performed by supplying pure water from above a rotation center in shower-like from an ejection nozzle while rotating the silicon wafer at a rotation speed of 50 rpm by a rotating device, and then the silicon wafer was spin-dried to form a pattern (pixel). Next, a heating treatment (post-baking) was performed for 300 seconds using a hot plate at 200° C. to form a pattern (pixel) of the cured film. The number of defects in the pattern of the obtained cured film was examined using a wafer defect evaluation device (ComPLUS3, manufactured by AMAT). Defects were evaluated according to the following standard.

A: total number of defects in 8-inch wafer <30

B: 30<total number of defects in 8-inch wafer <100

C: 100<total number of defects in 8-inch wafer

(Evaluation of Color Mixing)

The photosensitive resin composition was applied to a silicon wafer having a diameter of 8 inches (1 inch=25.4 mm). Next, a heating treatment (pre-baking) was performed for 120 seconds using a hot plate at 100° C. Next, using an i-ray stepper exposure device FPA-3000 i5+(manufactured by Canon Inc.), the silicon wafer was exposed at a wavelength of 365 nm at an exposure amount of 500 mJ/cm². As the mask, a mask having an island pattern of 2 cm×2 cm was used. Next, the substrate on which the irradiated coating film was formed was placed on a horizontal rotary table of a spin-shower developing machine (DW-30 Type, manufactured by Chemitronics Co., Ltd.), and subjected to a puddle development at room temperature for 60 seconds using an alkali developer (CD-2060, manufactured by Fujifilm Electronic Materials Co., Ltd.). Next, the substrate after the puddle development was fixed on the horizontal rotary table by a vacuum chuck method, a rinse treatment (23 seconds×2 times) was performed by supplying pure water from above a rotation center in shower-like from an ejection nozzle while rotating the silicon wafer at a rotation speed of 50 rpm by a rotating device, and then the silicon wafer was spin-dried to form a pattern (pixel). Next, a heating treatment (post-baking) was performed for 300 seconds using a hot plate at 200° C. to form a pattern of the cured film.

Light transmittance (transmittance) of the pattern of the obtained cured film in a wavelength range of 400 to 700 nm was measured by using MCPD-3000 manufactured by OTSUKA ELECTRONICS Co., LTD.

Next, a photosensitive resin composition for color mixing evaluation was spin-coated on the pattern of the cured film produced above, and subjected to a heating treatment (pre-baking) for 120 seconds using a hot plate at 100° C. to form a coating film having a thickness of 0.6 μm. As the photosensitive resin composition for color mixing evaluation, the above-described Yellow composition and Magenta composition were used.

Next, the substrate on which the coating film of the photosensitive resin composition for color mixing evaluation was formed was placed on a horizontal rotary table of a spin-shower developing machine (DW-30 Type, manufactured by Chemitronics Co., Ltd.), and subjected to a puddle development at room temperature for 60 seconds using an alkali developer (CD-2060, manufactured by Fujifilm Electronic Materials Co., Ltd.), thereby peeling off the coating film of the photosensitive resin composition for color mixing evaluation. Next, the substrate after the puddle development was fixed on the horizontal rotary table by a vacuum chuck method, a rinse treatment (23 seconds×2 times) was performed by supplying pure water from above a rotation center in shower-like from an ejection nozzle while rotating the silicon wafer at a rotation speed of 50 rpm by a rotating device, and then the silicon wafer was spin-dried to perform a color mixing evaluation test.

Light transmittance (transmittance) of the pattern of the cured film after the color mixing evaluation test in a wavelength range of 400 to 700 nm was measured by using MCPD-3000 manufactured by OTSUKA ELECTRONICS Co., LTD, the amount of change in integrated value of the transmittance was determined, and the color mixing was evaluated according to the following standard.

A: amount of change in integrated value of the transmittance was less than 1%.

B: amount of change in integrated value of the transmittance was 1% or more and less than 1.5%.

C: amount of change in integrated value of the transmittance was 1.5% or more.

TABLE 3

| | | Example 1 | Example 2 | Example 3 | Example 4 | Example 5 |
|---|---|---|---|---|---|---|
| Evaluation | Spectral characteristics | A | A | A | A | A |
| | as cyan color | | | | | |
| | Light resistance | B | A | A | A | A |
| | Rectangularity | A | A | A | A | A |
| | Defects | A | A | A | B | A |
| | Color mixing | A | A | A | A | A |
| | (Yellow composition) | | | | | |
| | Color mixing | A | A | A | A | A |
| | (Magenta composition) | | | | | |

TABLE 4

| | | Example 6 | Example 7 | Example 8 |
|---|---|---|---|---|
| Evaluation | Spectral characteristics | A | A | B |
| | as cyan color | | | |
| | Light resistance | B | A | A |
| | Rectangularity | A | B | B |
| | Defects | A | B | B |
| | Color mixing | A | A | A |
| | (Yellow composition) | | | |
| | Color mixing (Magenta | A | A | A |
| | composition) | | | |

TABLE 5

| | | Comparative | Comparative | Comparative | Comparative | Comparative |
|---|---|---|---|---|---|---|
| | | example 1 | example 2 | example 3 | example 4 | example 5 |
| Evaluation | Spectral characteristics | A | A | C | A | A |
| | as cyan color | | | | | |
| | Light resistance | C | A | A | C | C |
| | Rectangularity | A | C | A | A | A |
| | Defects | A | A | A | B | C |
| | Color mixing | A | C | A | A | A |
| | (Yellow composition) | | | | | |
| | Color mixing | A | C | A | A | A |
| | (Magenta composition) | | | | | |

As shown in the tables, Examples were excellent in the evaluations of the spectral characteristics as cyan color, the light resistance, and the color mixing.

### Example 100

A silicon wafer was coated with a Cyan composition using a spin coating method so that the thickness of a film after film formation was 1.0 μm. Next, the coating film was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, the Cyan composition was patterned by heating at 200° C. for 5 minutes using a hot plate. Likewise, the Yellow composition and the Magenta composition were sequentially patterned to form cyan, yellow, and magenta-colored patterns (Bayer pattern), thereby producing a color filter.

As the Cyan composition, the photosensitive resin composition of Example 2 was used.

As the Yellow composition and the Magenta composition, the above-described Yellow composition and Magenta composition were used, respectively.

The obtained color filter was incorporated into a solid-state imaging element according to a known method. The solid-state imaging element had a suitable image recognition ability.

What is claimed is:

1. A photosensitive resin composition comprising:
a colorant;
a resin;
a polymerizable compound;
a photopolymerization initiator;
an ultraviolet absorber; and
a solvent,
wherein the colorant includes at least one phthalocyanine pigment selected from Color Index Pigment Blue 15:3 or Color Index Pigment Blue 15:4, and includes 50 mass % or more of the phthalocyanine pigment, and
the ultraviolet absorber is contained in an amount of 0.1 to 10 mass % in a total solid content of the photosensitive resin composition.

2. The photosensitive resin composition according to claim 1,
wherein an average secondary particle diameter of the phthalocyanine pigment is 50 to 100 nm.

3. The photosensitive resin composition according to claim 1,
wherein the colorant is included in an amount of 10 mass % or more in the total solid content of the photosensitive resin composition.

4. The photosensitive resin composition according to claim 1,
wherein the resin includes a resin having an amine value of 25 to 60 mgKOH/g.

5. The photosensitive resin composition according to claim 4,
wherein the resin having an amine value of 25 to 60 mgKOH/g is a (meth)acrylic resin.

6. The photosensitive resin composition according to claim 1,
wherein the resin includes an alkali-soluble resin.

7. The photosensitive resin composition according to claim 1,
wherein the ultraviolet absorber is included in an amount of 1 to 200 parts by mass with respect to 100 parts by mass of the photopolymerization initiator.

8. The photosensitive resin composition according to claim 1,
wherein the ultraviolet absorber is included in an amount of 0.1 to 100 parts by mass with respect to 100 parts by mass of the polymerizable compound.

9. The photosensitive resin composition according to claim 1,
wherein the photosensitive resin composition is used for forming a pixel of a color filter.

10. The photosensitive resin composition according to claim 9,
wherein the photosensitive resin composition is used for forming a cyan pixel.

11. The photosensitive resin composition according to claim 1,
wherein the photosensitive resin composition is used for a solid-state imaging element.

12. A cured film formed from the photosensitive resin composition according to claim 1.

13. A color filter comprising:
the cured film according to claim 12.

14. A solid-state imaging element comprising:
the cured film according to claim 12.

15. The solid-state imaging element according to claim 14,
wherein the cured film is a cyan pixel, and
the solid-state imaging element further comprises:
a yellow pixel; and
a magenta pixel.

16. An image display device comprising:
the cured film according to claim 12.
